(19) United States
(12) Patent Application Publication
(10) Pub. No.: US 2012/0211049 A1
(43) Pub. Date: Aug. 23, 2012

(54) SOLAR CELL ELEMENT AND SOLAR CELL MODULE

(75) Inventors: Naoya Kobamoto, Higashiomi-shi (JP); Noriyasu Kawakita, Higashiomi-shi (JP)

(73) Assignee: KYOCERA CORPORATION, Kyoto (JP)

(21) Appl. No.: 13/504,122

(22) PCT Filed: Oct. 26, 2010
(86) PCT No.: PCT/JP2010/068982

§ 371 Date: Apr. 25, 2012

(30) Foreign Application Priority Data
Oct. 26, 2009 (JP) 2009-245513
Oct. 27, 2009 (JP) 2009-246843
Nov. 27, 2009 (JP) 2009-269805

(51) Int. Cl. H01L 31/05; H01L 31/0224

(52) U.S. Cl. 136/244; 136/256

(57) ABSTRACT

A semiconductor substrate comprising a first surface and a second surface, a first electrode, and a second electrode are arranged. The first electrode comprises a plurality of main electrodes located on the first surface and a plurality of first output taking parts electrically connected to the plurality of main electrodes and located on the second surface. The second electrode comprises one pair of collection parts located on the second surface to sandwich the first output taking parts and a connection part that electrically connects the one pair of collection parts to each other. The plurality of main electrodes comprise a first group located at first intervals and a second group located at second intervals. Third intervals between the first group and the second group are larger than the first and second intervals, and the connection part is located at positions corresponding to the third interval on the second surface.

### TECHNICAL FIELD

The present invention relates to a solar cell element and a solar cell module.

### BACKGROUND ART

As a type of a solar cell element, a back-contact type solar cell element is known (for example, see Patent Document 1).

The solar cell element includes a semiconductor substrate that exhibits one conductivity type, a opposite conductivity type layer that exhibits a conductivity type opposing that of the semiconductor substrate, a first electrode, and a second electrode having a polarity different from that of the first electrode. The semiconductor substrate includes a plurality of through holes that penetrate between a light-receiving surface and a rear surface. The opposite conductivity type layer includes a first opposite conductivity type layer formed on the light-receiving surface of the semiconductor substrate, a second opposite conductivity type layer formed on an internal surface of each of the through holes of the semiconductor substrate, and a third opposite conductivity type layer formed on a rear surface of the semiconductor substrate. The first electrode includes a light-receiving surface electrode part formed on the light-receiving surface of the semiconductor substrate, a through hole electrode part formed in each of the through holes, and a bus bar electrode part formed on the rear surface of the semiconductor substrate. The light-receiving surface electrode part, the through hole electrode part, and the bus bar electrode part are electrically connected to each other. The second electrode is formed on a portion where the third opposite conductivity type layer is not formed on the rear surface of the semiconductor substrate.

### PRIOR ART DOCUMENT

### Patent Document

Patent Document 1: WO 2008/078741

### SUMMARY OF THE INVENTION

### Problems to be Solved by the Invention

A solar cell module using the solar cell element described above is required to improve conversion efficiency of sunlight with a simple configuration in the context in which the solar cell module is expected to be more popularized. With respect to the improvement of the conversion coefficient, it is important that a loss of photovoltaic power be reduced.

The present invention has been made in consideration of the above problem and has as its object to provide an efficient solar cell element and an efficient solar cell module with simple configurations.

### Means for Solving the Problems

A solar cell element according to one embodiment of the present invention comprises a semiconductor substrate, a first electrode, and a second electrode. The semiconductor substrate comprises a first surface and a second surface on the rear side of the first surface and exhibits one conductivity type. The first electrode comprises a plurality of linear main electrode parts aligned on the first surface and a plurality of first output taking parts electrically connected to the main electrode parts and aligned on the second surface in a direction different from a longitudinal direction of the main electrode parts. The second electrode comprises one pair of collection parts arranged on the second surface to sandwich the first output taking parts, and a connection part arranged on the second surface and electrically connects the one pair of collection parts. The plurality of main electrode parts comprise a first electrode group including the main electrode parts aligned at first intervals D in a direction orthogonal to the longitudinal direction of the main electrode parts and a second electrode group including the main electrode parts aligned at second intervals E in the direction orthogonal to the longitudinal direction of the main electrode parts. In an alignment direction of the first output taking parts, a third interval F between the first electrode group and the second electrode group is larger than the first intervals D and the second intervals E. The connection part, in a planar perspective view from the first surface, is located at a position corresponding to the third interval F on the second surface.

### Effects of the Invention

According to the solar cell element described above, since an area for forming the connection part of the second electrode can be increased, an ohmic loss of the connection part can be reduced, and output characteristics of the solar cell element can be improved.

### BRIEF DESCRIPTION OF THE DRAWINGS

FIG. 1 is a plan view of a solar cell element 10 according to a first embodiment of the present invention when viewed from a first surface side.

FIG. 2 is a plan view of the solar cell element 10 when viewed from a second surface side.

FIG. 3(a) is a sectional schematic diagram when viewed from a section A-A in FIG. 1, and FIG. 3(b) is a sectional schematic diagram when viewed from a section B-B in FIG. 1.

FIG. 4 is an enlarged plan view of a part C in FIG. 2.

FIG. 5 is an enlarged plan view of a solar cell element 30 according to a second embodiment of the present invention when viewed from a second surface side.

FIG. 6 is an enlarged plan view of the solar cell element 30 when viewed from the first surface side.

FIG. 7 is an enlarged plan view of a solar cell element 40 according to a third embodiment of the present invention when viewed from the second surface side.

FIG. 8 is an enlarged plan view of a solar cell element 50 according to a fourth embodiment of the present invention when viewed from the second surface side.

FIG. 9 is a diagram schematically showing a configuration of a solar cell module 20 according to a fifth embodiment of the present invention.

FIG. 10 is an explanatory diagram showing details about a manner of connection between solar cell elements in the solar cell module 20.

FIG. 11 is an enlarged plan view of the solar cell module 20 when viewed from the second surface side.

FIG. 12 is a plan view of a solar cell element 70 in a solar cell module 60 according to a sixth embodiment of the present invention when viewed from the first surface side.

FIG. 13 is a plan view of the solar cell element 70 when viewed from the second surface side.

FIG. 14(a) is a sectional schematic diagram when viewed from a section J-J in FIG. 12, and FIG. 14(b) is a sectional schematic diagram when viewed from a section K-K in FIG. 12.

FIG. 15 is an enlarged plan view of a part L in FIG. 13.

FIG. 16 is a diagram schematically showing a configuration of the solar cell module 60, in which FIG. 16(a) is a side view and FIG. 16(b) is a plan view showing the configuration.

FIG. 17 is an explanatory diagram showing a manner of connection between the solar cell elements 70 in more detail in the solar cell module 60.

FIG. 18 is a partially enlarged plan view of the solar cell module 60 when viewed from the second surface side.

FIG. 19 is a partially enlarged perspective view of the solar cell module 60 when viewed from the second surface side.

FIG. 20 is a diagram for explaining an arrangement relation between the solar cell element 70, a protective layer 9, and a wiring material 15 in the solar cell module 60, in which FIG. 20(a) is a partially enlarged plan view showing an arrangement relation between the solar cell element 70 and the protective layer 9, and FIG. 20(b) is a partially enlarged sectional view for explaining an arrangement relation between the solar cell element 70, the protective layer 9, and the wiring material 15 shown in FIG. 14.

FIG. 21 is a diagram for explaining a shape of the wiring material 15 in a solar cell module 80 according to a seventh embodiment of the present invention, in which FIG. 21(a) is a partially enlarged perspective view of the solar cell module 80, and FIG. 21(b) is a partially enlarged sectional view of the solar cell module 80.

FIG. 22 is a diagram for explaining a shape of the wiring material 15 in a solar cell module 90 according to an eighth embodiment of the present invention, in which FIG. 22(a) is a partially enlarged perspective view of the solar cell module 90, and FIG. 22(b) is a partially enlarged sectional view of the solar cell module 90.

### EMBODIMENTS FOR CARRYING OUT THE INVENTION

Embodiments of the present invention will be described below in detail with reference to the accompanying drawings.

### Structure of Solar Cell Element

### First Embodiment

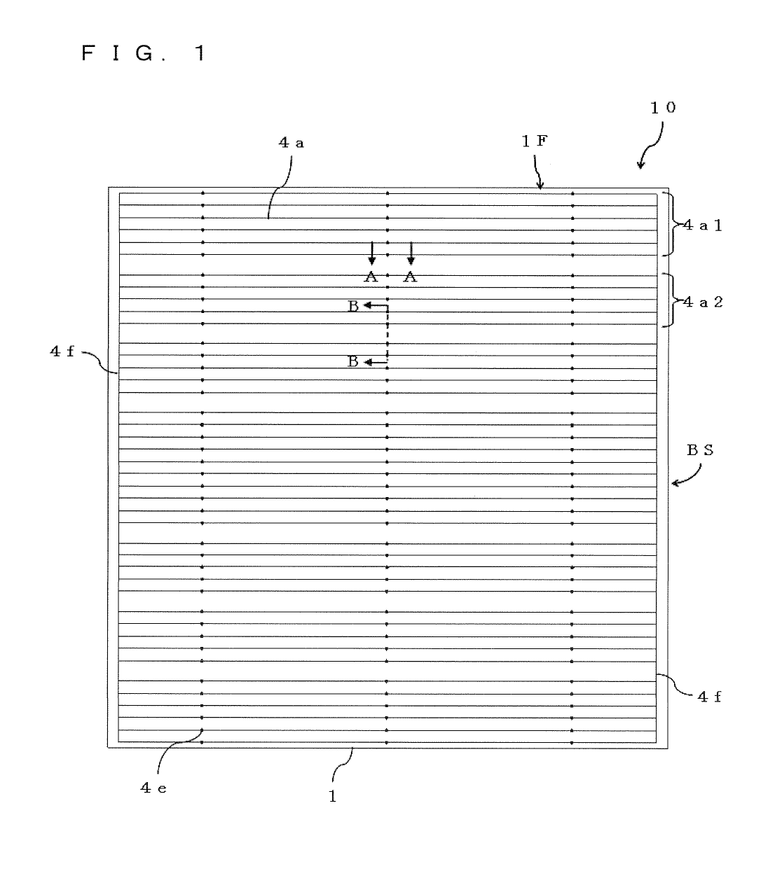

A solar cell element 10 according to a first embodiment of the present invention will be described below with reference to FIG. 1 to FIG. 4. The solar cell element 10 according to the first embodiment includes a semiconductor substrate 1 that exhibits one conductivity type, a opposite conductivity type layer 2 having a conductivity type different from that of the semiconductor substrate 1, a through hole 3, a first electrode 4, a second electrode 5, a semiconductor layer 6, and an antireflective layer 7.

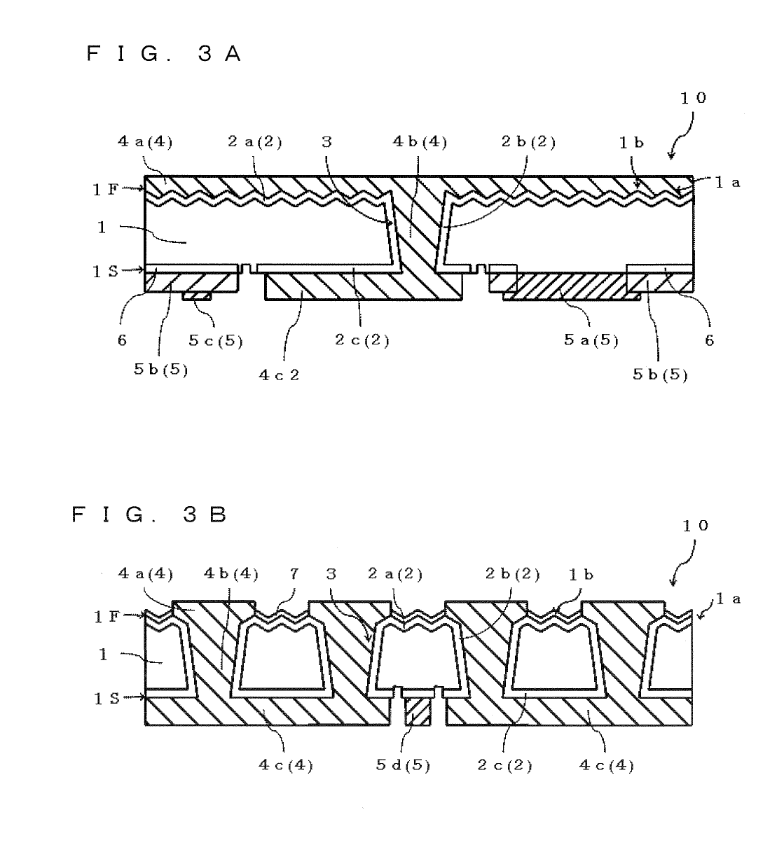

The semiconductor substrate 1 includes a first surface 1F (upper surface side in FIG. 3) and a second surface 1S (lower surface side in FIG. 3) on a rear side of the first surface 1F. In the solar cell element 10, the first surface 1F serves as a light-receiving surface. For descriptive convenience, the first surface 1F may be called the light-receiving surface of the semiconductor substrate 1, and the second surface 1S may be called a rear surface of the semiconductor substrate 1 or the like.

As the semiconductor substrate 1, a crystalline silicon substrate such as a single-crystal silicon substrate or a poly-crystal silicon substrate that contains a predetermined dopant element (impurity for controlling a conductivity type) and exhibits one conductivity type (for example, p type) is used. The thickness of the semiconductor substrate 1 can be set to, for example, 250 μm or less, and, furthermore, 150 μm or less. The shape of the semiconductor substrate 1 is not limited to a specific shape. However, the shape may be rectangular in terms of manufacturing processes.

In the embodiment, as the semiconductor substrate 1, a crystalline silicon substrate that exhibits a p-type conductivity type is used. When the semiconductor substrate 1 comprised of a crystalline silicon substrate is designed to exhibit a p type, as a dopant element, for example, boron or gallium can be used.

On the first surface 1F of the semiconductor substrate 1, as shown in

FIG. 3, a texture structure (uneven structure) 1a including a large number of small projections 1b is formed. In this manner, reflection of incident light on the first surface 1F is reduced to make it possible to cause sunlight to be maximally absorbed in the semiconductor substrate 1. The texture structure 1a is not a necessary configuration in the embodiment, and may be formed as needed.

The semiconductor substrate 1, as shown in FIG. 3, includes a plurality of through holes 3 that penetrate the semiconductor substrate 1 from the first surface 1F to the second surface 1S. The through hole 3, as will be described later, includes a second layer 2b formed on the internal surface of the through hole. A conduction part 4b of the first electrode 4 is formed inside the through hole 3. The through holes 3 can be formed at predetermined intervals to have diameters ranging from 50 μm or more to 300 μm or less. The through hole 3 may have different diameters of openings on the first surface 1F and the second surface 1S. For example, as shown in FIG. 3, the through hole 3 may have a shape the diameter of which decreases from the first surface 1F side to the second surface 1S side.

The opposite conductivity type layer 2 is a layer that exhibits a conductivity type opposing that of the semiconductor substrate 1. The opposite conductivity type layer 2 includes a first layer 2a formed on the first surface 1F of the semiconductor substrate 1, the second layer 2b formed on the internal surface of the through hole 3, and a third layer 2c formed on the second surface 1S of the semiconductor substrate 1. When a silicon substrate that exhibits a p-type conductivity type is used as the semiconductor substrate 1, the opposite conductivity type layer 2 is formed to exhibit an n-type conductivity type.

The first layer 2a, for example, is formed to be of an n+ type having a sheet resistance of about 60 to 300 Ω/□. When the value of the sheet resistance is set in the range, an increase in surface recombination and an increase in surface resistance on the first surface 1F can be reduced. The first layer 2a, for example, is formed on the first surface 1F of the semiconductor substrate 1 to have a thickness of about 0.2 μm to 0.5 μm.

The second layer 2b is formed in the through hole 3. The second layer 2b may have a sheet resistance equal to that of the first layer 2a. The second layer 2b may have a sheet resistance lower than the sheet resistance of the first layer 2a. In this case, the increase in surface resistance can be more reduced.

The third layer 2c is formed in a forming area of the first electrode 4 and a peripheral portion thereof on the second surface 1S of the semiconductor substrate 1.

When the opposite conductivity type layer 2 is arranged, in the solar cell element 10, a p-n junction is formed between an area of one conductivity type and the opposite conductivity type layer 2 in the semiconductor substrate 1.

The semiconductor layer 6 is a layer formed to form an internal electric field inside the solar cell element 10 (to obtain a so-called BSF effect (Back Surface Field Effect)). In this manner, a decrease in power generation efficiency caused by recombination of carriers near the second surface 1S of the semiconductor substrate 1 can be reduced.

The semiconductor layer 6 is formed on an almost entire surface except for an area in which the third layer 2c is formed on the second surface 1S of the semiconductor substrate 1. More specifically, the semiconductor layer 6 is formed on the second surface 1S not to be in contact with the third layer 2c. A concrete forming pattern of the semiconductor layer 6 varies depending on a forming pattern of the first electrode 4. A p-n isolation area is formed between the third layer 2c and the semiconductor layer 6 and on a peripheral portion of the second surface 1S of the semiconductor substrate 1. The p-n isolation area includes an area of one conductivity type of the semiconductor substrate 1.

The semiconductor layer 6 exhibits the same conductivity type as that of the semiconductor substrate 1. A concentration of a dopant contained in the semiconductor layer 6 is higher than a concentration of a dopant contained in the semiconductor substrate 1. More specifically, in the semiconductor layer 6, a dopant element is present at a concentration higher than a concentration of a dopant element doped to cause the semiconductor substrate 1 to exhibit one conductivity type. The semiconductor layer 6 is formed by diffusing, for example, a dopant element such as boron or aluminum into the second surface 1S when the semiconductor substrate 1 exhibits a p-type. At this time, a concentration of a dopant element contained in the semiconductor layer 6 can be set to about 1×10¹⁸ to 5×10²¹ atoms/cm³. In this manner, the semiconductor layer 6 exhibits a p+-type conductivity type containing a dopant having a concentration higher than that of a p-type conductivity type exhibited by the semiconductor substrate 1, and forms a preferable ohmic contact with a first collection part 5b (will be described later).

The semiconductor layer 6, for example, may be formed to occupy 70% or more of the entire area of the second surface 1S when the second surface 1S of the semiconductor substrate 1 is planarly viewed. In this case, the BSF effect that improves output characteristics of the solar cell element 10 can be obtained.

The semiconductor layer 6 is not a necessary configuration in the embodiment, and may be formed as needed.

The antireflective layer 7 is formed on the first surface 1F of the semiconductor substrate 1. The antireflective layer 7 has a role to reduce reflection of incident light on the surface (first surface 1F) of the semiconductor substrate 1, and is formed on the first layer 2a. The antireflective layer 7 can be made of a silicon nitride film, an oxide material film, or the like. A preferable thickness of the antireflective layer 7 varies depending on construction materials. However, the thickness is set to a value at which a reflection-free condition is realized for incident light. For example, when a silicon substrate is used as the semiconductor substrate 1, the antireflective layer 7 may be formed by a material having a refraction index of about 1.8 to 2.3 to have a thickness of about 500 to 1200_{A}.

The antireflective layer 7 is not necessarily arranged in the embodiment, and may be arranged as needed.

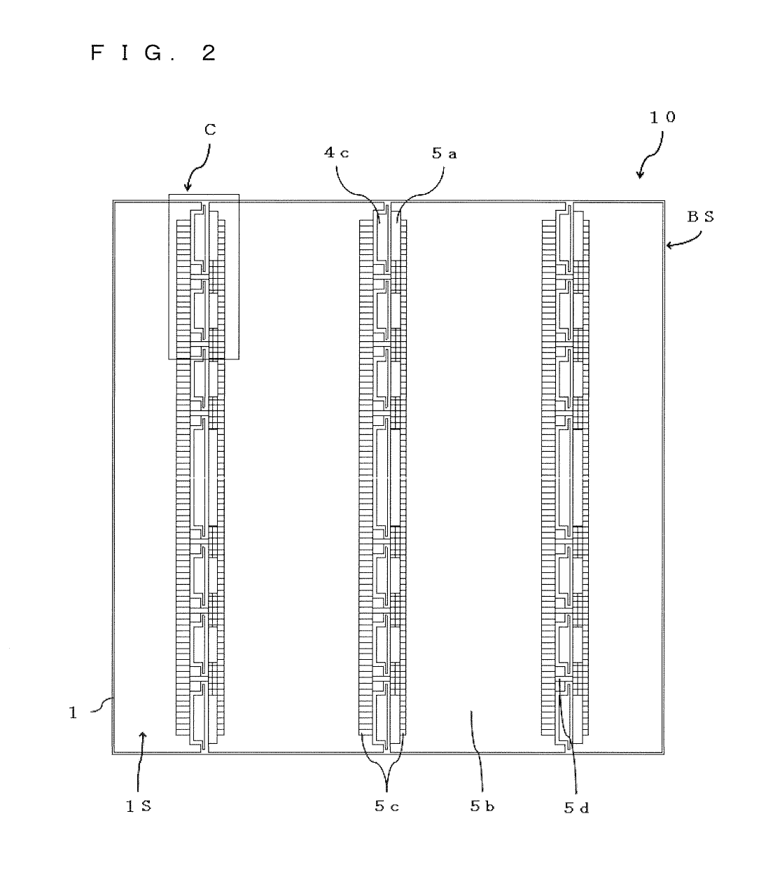

The first electrode 4 includes a plurality of main electrode parts 4a, a plurality of conduction parts 4b, and a plurality of first output taking part 4c. As shown in FIG. 1 and FIG. 3(a), the main electrode part 4a is formed on the first surface 1F of the semiconductor substrate 1, and the conduction part 4b is electrically connected to the main electrode part 4a and is formed in the through hole 3. As shown in FIG. 2 and FIG. 3(a), the first output taking part 4c is formed on the second surface 1S and connected to the conduction part 4b.

The main electrode parts 4a has a function of collecting carriers generated on the first surface 1F side. The conduction part 4b has a function of guiding the carriers collected by the main electrode part 4a to the first output taking part 4c arranged on the second surface 1S. The first output taking part 4c functions as a wiring connection part connected to a wire that electrically connects adjacent solar cell elements to each other.

The conduction part 4b, as shown in FIG. 1, is arranged to correspond to the through hole 3 formed in the semiconductor substrate 1. The conduction part 4b, as shown in FIG. 3, is arranged to be derived from the first surface 1F side to the second surface 1S side of the semiconductor substrate 1. In FIG. 1, a forming position of the conduction part 4b shown as a solid circle corresponds to a forming position of the through hole 3.

In the embodiment, the plurality of conduction parts 4b are arranged in a predetermined direction. In the solar cell element 10, as shown in FIG. 1, the plurality of conduction parts 4b are arranged in a direction parallel to a reference side BS of the first surface 1F of the semiconductor substrate 1 to form a plurality of columns (3 columns in FIG. 1). In this case, the reference side BS is a side that is parallel to an alignment direction of the solar cell element 10 when the plurality of solar cell elements 10 are arranged to form the solar cell module 20. The parallel in the specification should not be strictly understood unlike in mathematical definition.

In the solar cell element 10, the conduction parts 4b are arranged to be aligned in a plurality of straight lines (3 lines in FIG. 1). The plurality of conduction parts 4b in the columns are arranged at almost equal intervals.

The main electrode part 4a connects the conduction parts 4b belonging to different columns to each other on the first surface 1F of the semiconductor substrate 1. The main electrode part 4a is linear. In the embodiment, the linear main electrode part 4a, for example, as shown in FIG. 1, is arranged to extend in a direction orthogonal to the alignment direction of the conduction parts 4b, i.e., in a direction orthogonal to the reference side BS. The main electrode part 4a arranged as described above connects the three conduction parts 4b located on a straight line orthogonal to the reference side BS. In this manner, when light is equally irradiated on the first surface 1F, an increase in ohmic loss generated by causing a current to concentrically flowing in one of the conduction parts 4b can be reduced. Thus, deterioration of the output characteristics of the solar cell element can be reduced.

The width of the main electrode part 4a can be set to about 50 to 200 μm, and an interval between the main electrode parts 4a can be set to about 1 to 3 mm.

In the embodiment, the number of conduction parts 4b aligned in a direction along the reference side BS is equal to the number of main electrode parts 4a. In this manner, an increase in ohmic loss of a light-receiving surface electrode part can be reduced while keeping a light-receiving area on the first surface 1F.

The first electrode 4, as shown in FIG. 1, is arranged to cover the through hole 3, and may have a circular pad electrode part 4e having a diameter larger than the diameter of the through hole 3. In the configuration described above, even though a forming position of the main electrode part 4a shifts from a desired position in the manufacturing process, the main electrode part 4a and the conduction part 4b can be connected to each other. In this manner, the reliability of the solar cell element can be improved.

The first electrode 4, as shown in FIG. 1, may include an auxiliary electrode part 4f that connects ends of the main electrode parts 4a to each other. The auxiliary electrode part 4f has a function of electrically connecting the adjacent linear main electrode parts 4a to each other. According to the embodiment, if the main electrode part 4a may be partially disconnected, carriers can be guided to the other main electrode parts 4a through the auxiliary electrode part 4f. For this reason, a decrease in output of the solar cell element 10 can be reduced.

In the solar cell element 10 described above, when a portion formed on the first surface 1F side serving as the light-receiving surface of the first electrode 4 is used as a light-receiving surface electrode part, a proportion of the light-receiving surface electrode part to the entire area of the first surface 1F serving as a light-receiving surface is very low. For this reason, high light-receiving efficiency is realized. Furthermore, since the light-receiving surface electrode part is uniformly formed on the first surface 1F, carriers generated on the first surface 1F can be efficiently collected.

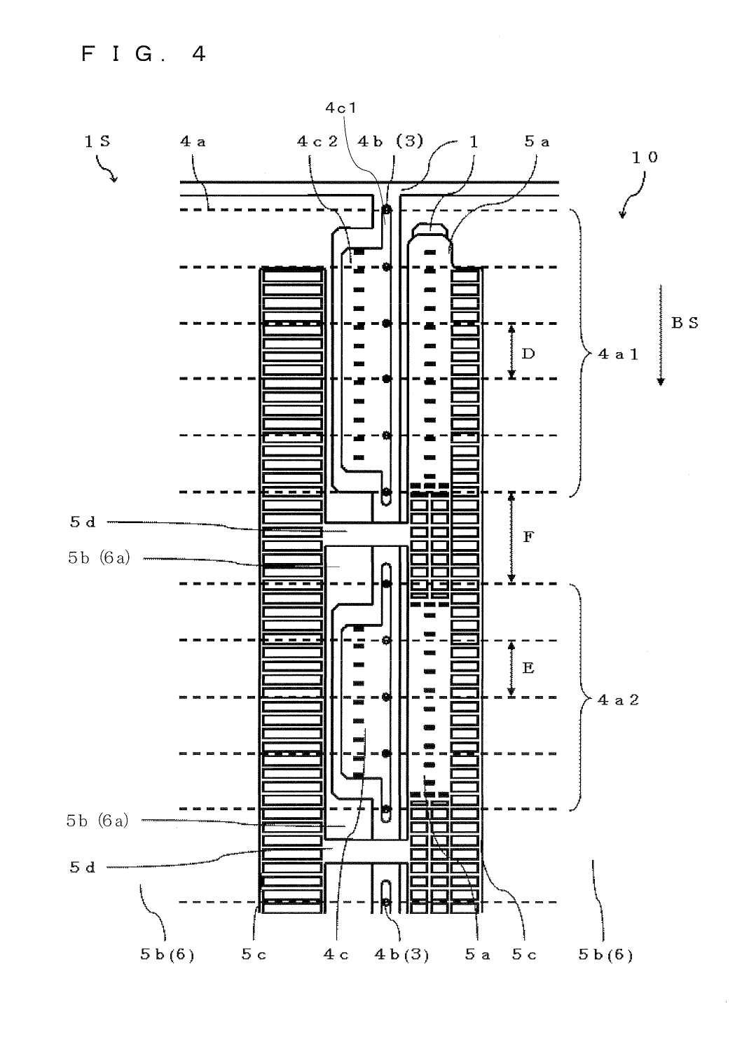

Furthermore, the first electrode 4, as shown in FIG. 3(b) and FIG. 4, on the second surface 1S of the semiconductor substrate 1, includes the plurality of first output taking parts 4c arranged at positions corresponding to the plurality of conduction parts 4b (through holes 3).

The first output taking parts 4c are sequentially aligned in a direction (alignment direction of the conduction parts 4b in the embodiment) different from the longitudinal direction of the main electrode parts 4a, and formed to have long-sheet shapes having a longitudinal direction in the alignment direction. In the embodiment, one of the first output taking parts 4c and the plurality of conduction parts 4b are connected to each other. Specifically, as shown in FIG. 4, one of the first output taking parts 4c is connected to the five or six conduction parts 4b.

The first output taking parts 4c are formed in a plurality of columns (3 columns in FIG. 2) to correspond to the alignment of the conduction parts 4b. In the following description, the direction in which the plurality of first output taking parts 4c are aligned, i.e., a direction along the reference side BS (direction parallel to the reference side BS) is called an alignment direction. The alignment direction is the same direction as the direction in which the conduction parts 4b are aligned.

On the other hand, the second electrode 5 has a polarity different from that of the first electrode 4, and is arranged to be insulated from the first electrode 4. The second electrode 5 described above, as shown in FIG. 2 and FIG. 4, includes a second output taking part 5a, one pair of first collection parts 5b, one pair of second collection parts 5c, and a connection part 5d.

The second output taking part 5a is formed on the second surface 1S. One pair of first collection parts 5b are arranged on both sides that sandwich the first output taking part 4c when the second surface 1S is planarly viewed. One pair of second collection parts 5c, as shown in FIG. 3(a) and FIG. 4, is formed on the first collection part 5b, and is formed by thin lines to have a lattice shape. The connection part 5d electrically connects one pair of first collection parts 5b to each other, and electrically connects the second collection part 5c and the second output taking part 5a to each other.

The second collection part 5c is not necessarily arranged in the embodiment, and may be arranged as needed. Thus, when the second collection parts 5c are not formed, the connection part 5d, when the second surface 1S is planarly viewed, electrically connects one pair of first collection parts 5b to sandwich the first output taking part 4c, or electrically connects one of the first collection parts 5b to the second output taking part 5a located on an opposite side through the first output taking part 4c.

The first collection part 5b is formed on the semiconductor layer 6 arranged on the second surface 1S of the semiconductor substrate 1, and collects carriers generated on the second surface 1S side. The first collection part 5b is formed on an almost entire surface of the second surface 1S except for the first output taking part 4c, the peripheral portion thereof, and a part of an area in which the second output taking part 5a is formed. In other words, the first collection parts 5b are paired with each other to sandwich the first output taking part 4c when the second surface 1S is planarly viewed.

In this case, the “almost entire surface” is a surface of 70% or more of the entire area of the second surface 1S when the second surface 1S of the semiconductor substrate 1 is planarly viewed. When the first collection part 5b is formed on an almost entire surface except for an area in which the first electrode 4 is formed on the second surface 1S, a moving distance of carriers collected by the first collection part 5b can be shortened. For this reason, since the number of carriers taken out of the second output taking part 5a can be increased, the output characteristics of the solar cell element 10 can be improved.

The second output taking part 5a roles as a wiring connection part connected to a wire that electrically connects adjacent solar cell elements to each other. The second output taking part 5a may include at least a part overlapping the first collection part 5b. For this reason, the carriers collected by the first collection part 5b can be output to the outside. For this reason, the second output taking part 5a, as shown in FIG. 3(a), may be arranged in an area in which the first collection part 5b is not formed on the second surface 1S.

The second output taking part 5a is arranged in parallel to the plurality of first output taking parts 4c, and has a long-sheet shape having a longitudinal direction in an alignment direction like the first output taking parts 4c. In the embodiment, the plurality of second output taking parts 5a, as described above, are formed along the alignment direction of the first output taking parts 4c. However, one belt-like second output taking part 5a may be formed.

The lengths of the first output taking part 4c and the second output taking part 5a along the reference side BS may be equal to each other or different from each other.

As shown in FIG. 4, on the peripheral portion side of the semiconductor substrate 1 of the second output taking part 5a located at the peripheral portion of the semiconductor substrate 1, the second output taking part 5a may be connected to the semiconductor substrate 1 without being connected to the first collection part 5b. In this manner, the possibility of peeling the second output taking part 5a by an influence of expansion and contraction of the wiring material 15 caused by daily temperature cycling when the solar cell module including the solar cell element 10 (will be described later) is installed outside the house can be reduced.

The connection part 5d is formed in an area in which the first output taking part 4c is not formed on the second surface 1S. The solar cell element 10 having the connection part 5d can efficiently guide carriers collected by the second electrode 5 (the first collection part 5b and the second collection parts 5c) formed on the opposite side of the second output taking part 5a through the first output taking part 4c adjacent to the second output taking part 5a to the second output taking part 5a.

The first collection part 5b may be comprised of aluminum for example. The second output taking part 5a, the second collection parts 5c, and the connection part 5d can be comprised of silver, for example. The connection part 5d, for example, may be comprised of aluminum or a material obtained by forming silver on aluminum.

In the embodiment, as shown in FIG. 1 and FIG. 4, the plurality of main electrode parts 4a include a first electrode group 4a1 and a second electrode group 4a2. The first electrode group 4a1 includes the plurality of main electrode parts 4a that are aligned at first intervals D in a direction orthogonal to the longitudinal direction of the main electrode parts 4a. The second electrode group 4a2 includes the plurality of main electrode parts 4a that are aligned at second intervals E in a direction orthogonal to the longitudinal direction of the main electrode parts 4a.

The numbers of first electrode groups 4a1 and second electrode groups 4a2 are not limited to specific numbers, and may be changed depending on arrangements of the connection parts 5d (will be described later).

In the embodiment, as shown in FIG. 4, the first interval D and the second interval E are equal to each other. However, the intervals may be different from each other.

The first electrode groups 4a1 and the second electrode group 4a2 that are adjacent to each other are formed on the first surface 1F at third intervals F in an alignment direction of the first output taking parts 4c. The third intervals F in the alignment direction of the first output taking parts 4c are larger than the first intervals D and the second intervals E. Furthermore, in the embodiment, the connection parts 5d are arranged at positions corresponding to the third intervals F on the second surface 1S when viewed through in plan view from the first surface 1F.

According to the embodiment, since a wide space can be formed between the first output taking part 4c connected to the first electrode group 4a1 and the first output taking part 4c connected to the second electrode group 4a2, the connection part 5d can have a large width. In this manner, an electric power collected by the first collection part 5b can be efficiently guided to the second output taking part 5a.

When the first intervals D and the second intervals E, for example, are set 1 mm to 2.8 mm, the third intervals F can be set to be larger than the first intervals D and the second intervals E and set to 1.05 mm to 3 mm.

In the embodiment, as shown in FIG. 4, the first output taking part 4c includes a conductor area 4c1 (overlapping portion) connected to the conduction part 4b and a taking area 4c2 connected to the conductor area 4c1.

The conductor area 4c1 is arranged to cover some of the plurality of conduction parts 4b. The taking area 4c2, as shown in FIG. 3(a) and FIG. 4, on the second surface 1S of the semiconductor substrate 1, is located immediately below the plurality of conduction parts 4b (through holes 3). The conductor area 4c1 has a long-sheet shape having a longitudinal direction in the alignment direction (direction along the reference side BS) of the conduction parts 4b. More specifically, the conductor area 4c1 is formed along the alignment direction of the conduction parts 4b. In the embodiment, each of the conductor areas 4c1 is connected to the plurality of conduction parts 4b, and the plurality of conductor areas 4c1 are aligned along the alignment direction of the conduction parts 4b. Specifically, as shown in FIG. 4, the conductor area 4c1 corresponding to the first electrode group 4a1 is connected to the six conduction parts 4b, and the conductor area 4c1 corresponding to the second electrode group 4a2 is connected to the five conduction parts 4b.

Since the conductor area 4c1 need only be electrically connected to the conduction part 4b, the conductor area 4c1 may have a shape that partially covers the conduction part 4b.

The taking area 4c2, on the second surface 1S, is adjacent to each of the conductor areas 4c1 and connected to each of the conductor area portions 4c1. The taking area 4c2 is arranged between the conductor area 4c1 and the first collection part 5b. The taking area 4c2, like the conductor area 4c1, has a long-sheet shape having a longitudinal direction along the alignment direction of the conduction parts 4b. The taking areas 4c2, as shown in FIG. 4, are aligned to be connected to the conductor areas 4c1 along the alignment direction of the conduction parts 4b.

The conductor areas 4c1 and the taking areas 4c2 are formed in a plurality of columns (3 columns in FIG. 2) in accordance with the number of columns of the aligned conduction parts 4b.

In the embodiment, as shown in FIG. 4, in the alignment direction of the conduction parts 4b, the length of the taking area 4c2 is shorter than the length of the conductor area 4c1. As shown in FIG. 4, the semiconductor layer 6 includes an extending portion 6a located between the adjacent taking areas 4c2 in the alignment direction of the first output taking parts 4c.

In this manner, in the embodiment, since the semiconductor layer 6 is also formed between the first output taking parts 4c that are adjacent to each other in the alignment direction of the first output taking parts 4c, the forming area of the semiconductor layer 6 on the second surface 1S can be increased. As a result, since the BSF effect occurring in the interface between the semiconductor substrate 1 and the semiconductor layer 6 can be enhanced, the output characteristics of the solar cell element 10 can be improved.

Furthermore, in the embodiment, the first collection part 5b is formed on the extending portion 6a of the semiconductor layer 6 located between the taking areas 4c2 in the alignment direction of the first output taking parts 4c. In this manner, on the second electrode 5 formed on the second surface 1S, an area in which only the narrow connection part 5d is present can be reduced in size. As a result, the ohmic loss of the second electrode 5 is reduced, and the output characteristics of the solar cell element 10 can be improved.

The length (size along the alignment direction of the first output taking parts 4c) of the conductor area 4c1 in the longitudinal direction of the conductor areas 4c1 may be set to cover the plurality of conduction parts 4b and may be set to 8 to 15 mm, for example.

The width (size along the direction orthogonal to the alignment direction of the first output taking parts 4c) of the conductor area 4c1 may be set to cover the conduction parts 4b and may be set to 0.1 to 1 mm, for example.

The length (size along the alignment direction of the first output taking parts 4c) of the taking area 4c2 in the longitudinal direction is a length at which the wiring material 15 that connect s the adjacent solar cell elements to each other can connect with the taking area 4c2, need only be shorter than that of the conduction part 4b, and can be set to 4 to 10 mm, for example.

The width (size along a direction orthogonal to the alignment direction of the first output taking parts 4c) of the taking area 4c2 may be equal to or larger than the width of the wiring material 15 (will be described later), and can be set to 1.5 to 4 mm, for example.

Furthermore, as shown in FIG. 1, in the embodiment, as described above, the conduction parts 4b are arranged in a plurality of columns. In this manner, when n (n is an integer that is 2 or more) alignments of the conduction parts 4b are arranged in parallel to the reference side BS of the first surface 1F of the semiconductor substrate 1, the columns of the conduction parts 4b are arranged on odd-number-th division lines of (2n-1) division lines DS that equally divide one side of the semiconductor substrate 1 perpendicular to the reference side BS by 2n. In this manner, the ohmic loss of the main electrode part 4a can be efficiently reduced, and the beauty can be added. Thus, when the conductor areas 4c1 are arranged, the adjacent solar cell elements are arranged to be rotationally symmetrical to each other even though the columns of the conduction parts 4b are arranged on the division lines to make it possible to connect the wiring material 15. When a distance between the column of the conduction part 4b and the division line is 2 mm or less, it can be understood the column of the conduction parts are located on the division line.

As described above, in the embodiment, the first output taking part 4c includes a flared portion. However, the flared portion need not be formed.

### Second Embodiment

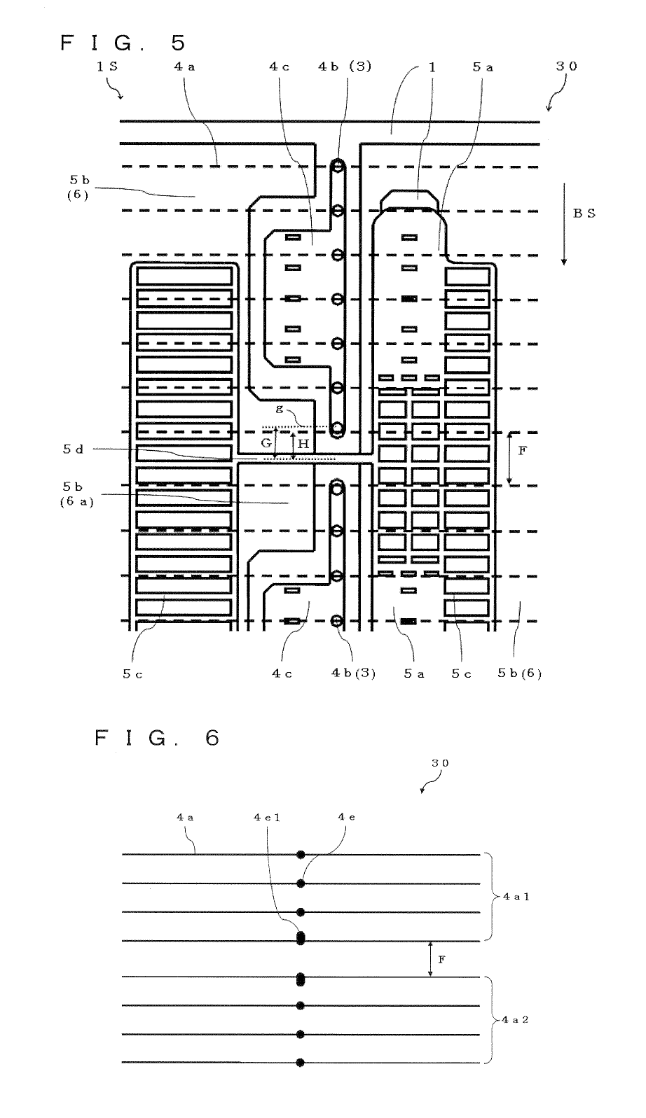

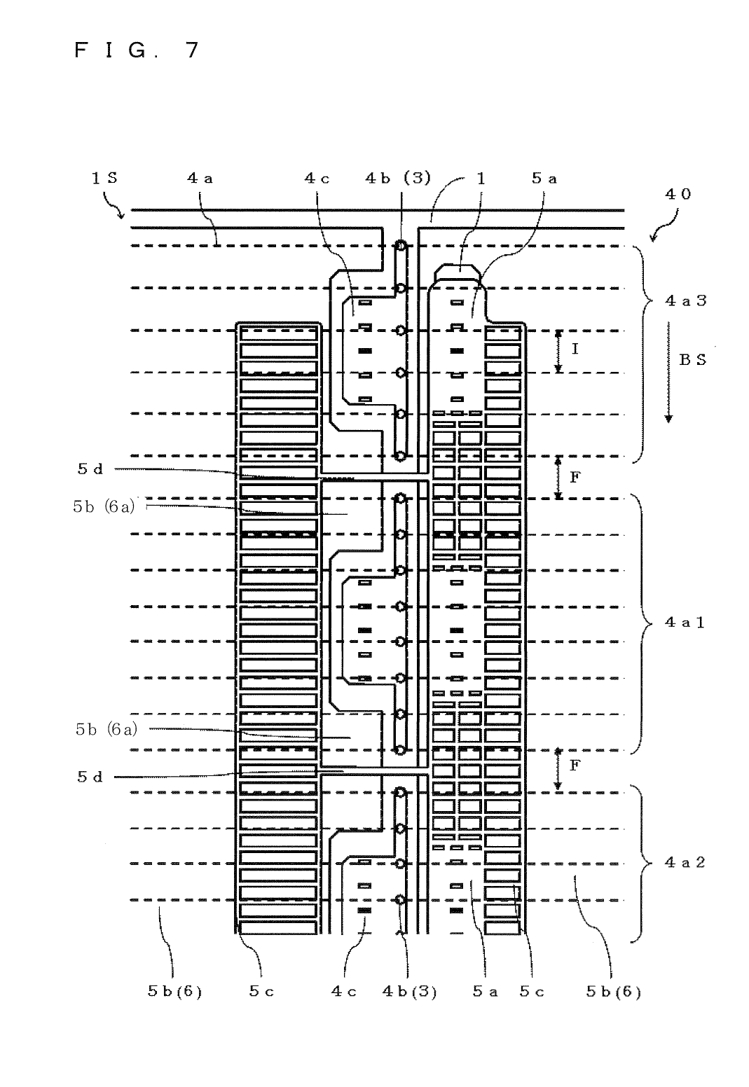

Next, a solar cell element 30 according to a second embodiment of the present invention will be described below with reference to FIG. 5 and FIG. 6. A description of the same configuration as that of the first embodiment will be omitted.

In the embodiment, the arrangement of the conduction part 4b adjacent to the connection part 5d is different from that in the first embodiment. Specifically, in the embodiment, as shown in FIG. 5, when viewed through in plan view from the second surface 1S, a distance G between the connection part 5d and the conduction part 4b adjacent to the connection part 5d is longer than a distance H between the connection part 5d and the main electrode part 4a adjacent to the connection part 5d.

With the above configuration, a space between the first output taking part 4c connected to the first electrode group 4a1 and the first output taking part 4c connected to the second electrode group 4a2 can be more increased. In this manner, the width of the connection part 5d can be more increased. As a result, an electric power collected by the first collection part 5b can be efficiently guided to the second output taking part 5a.

In this case, the distance G, as shown in FIG. 5, is a distance between the center of the conduction part 4b and the center of the connection part 5d in a width direction (direction parallel to the reference side BS). In FIG. 5, the distance G is indicated by an arrow that connects an imaginary line g extending from the center of the conduction part 4b to the center of the connection part 5d in the width direction.

The distance H, as shown in FIG. 5, is a distance between the center line of the main electrode part 4a in a width direction (direction parallel to the reference side BS) and the center line of the connection part 5d in a width direction (direction parallel to the reference side BS).

In the first embodiment, the conduction part 4b is arranged immediately below the main electrode part 4a to cause the center line of the main electrode part 4a to overlap the center of the conduction part 4b. For this reason, a distance between the adjacent main electrode parts 4a is equal to a distance between the adjacent conduction parts 4b. Thus, in the first embodiment, the distance G is equal to the distance H.

In the embodiment, a pad electrode part 4e1 that is proximate to the third intervals F of the plurality of pad electrode parts 4e, as shown in FIG. 6, is formed in an oval shape or an elliptic portion to be connected to the main electrode part 4a and the conduction part 4b, for example. A size of the pad electrode part 4e in a minor-axis direction is, for example, 100 μm or more and 500 μm or less. The plurality of pad electrode parts 4e including the pad electrode part 4e1, on the first surface 1F side, are formed to correspond to the main electrode parts 4a, respectively. For this reason, when the pad electrode parts 4e include the pad electrode part 4e1 described above, the plurality of pad electrode parts 4e are apparently arranged at almost equal intervals to make it possible to improve the appearance.

### Third Embodiment

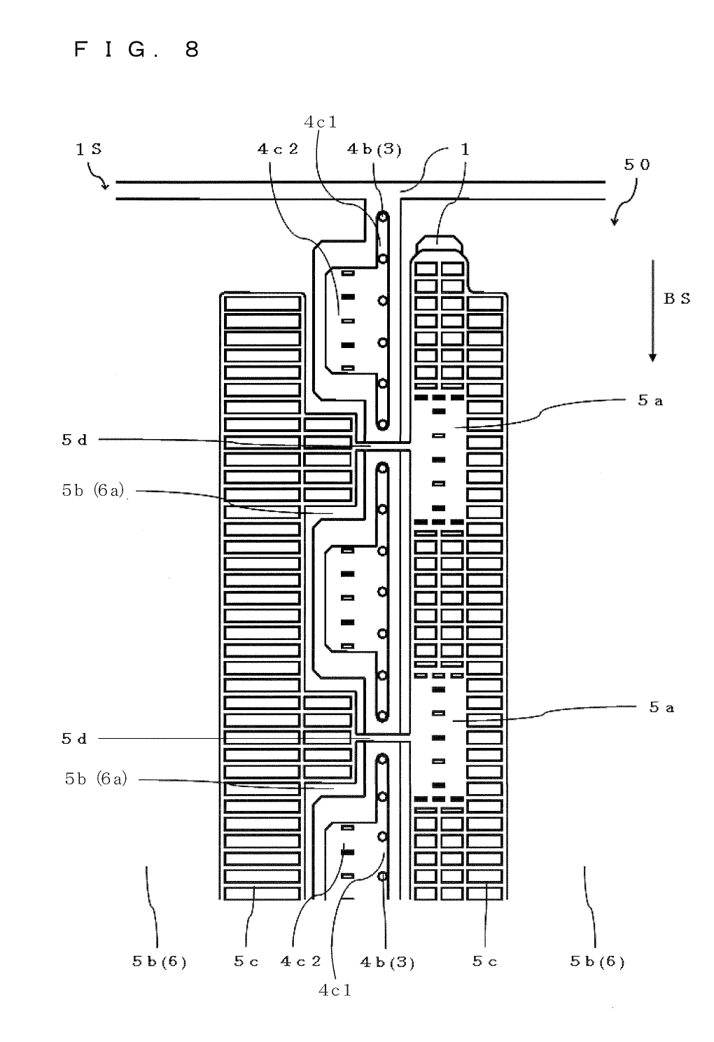

Next, a solar cell element 40 according to a third embodiment of the present invention will be described below with reference to FIG. 7. A description of the same configuration as that of the first embodiment will be omitted.

In the embodiment, the arrangement of the main electrode parts 4a is different from that in the first embodiment. Specifically, in the embodiment, as shown in FIG. 7, the plurality of main electrode parts 4a further include a third electrode group 4a3. The third electrode group 4a3 is arranged outside the first electrode group 4a1 and the second electrode group 4a2. The third electrode group 4a3 is arranged at a third interval F from the first electrode group 4a1. The plurality of main electrode parts 4a in the third electrode group 4a3 are aligned at fourth intervals I each of which is equal to larger than the third gap F in an alignment direction of the first output taking parts 4c.

In the solar cell module (will be described later), light irregularly reflected by a rear-surface protective material may be reflected by a transparent substrate and incident on an outer peripheral side of the first surface 1F of the semiconductor substrate 1. According to the embodiment including the third electrode group 4a3, an amount of light received on the outer peripheral side of the solar cell element 10 (semiconductor substrate 1) can be increased. For this reason, the output characteristics of the solar cell element 10 can be improved.

Each of the fourth intervals I can be set to 1.5 to 3 mm, for example. As shown in FIG. 7, in the embodiment, a distance between the third electrode group 4a3 and the first electrode group 4a1 is equal to the third interval F. However, the distance is not limited to the interval, and may be a predetermined distance.

As shown in FIG. 7, in the embodiment, the first electrode group 4a1 and the third electrode group 4a3 are adjacent to each other. However, the second electrode group 4a2 and the third electrode group 4a3 may be adjacent to each other.

When differences between the intervals (the first intervals D, the second intervals E, and the fourth intervals I) of the adjacent main electrode parts 4a in the electrode groups and the third intervals F are set to be 0.2 mm or less, it appears that the main electrode parts 4a are arranged at equal intervals. For this reason, a preferable appearance can be obtained.

### Fourth Embodiment

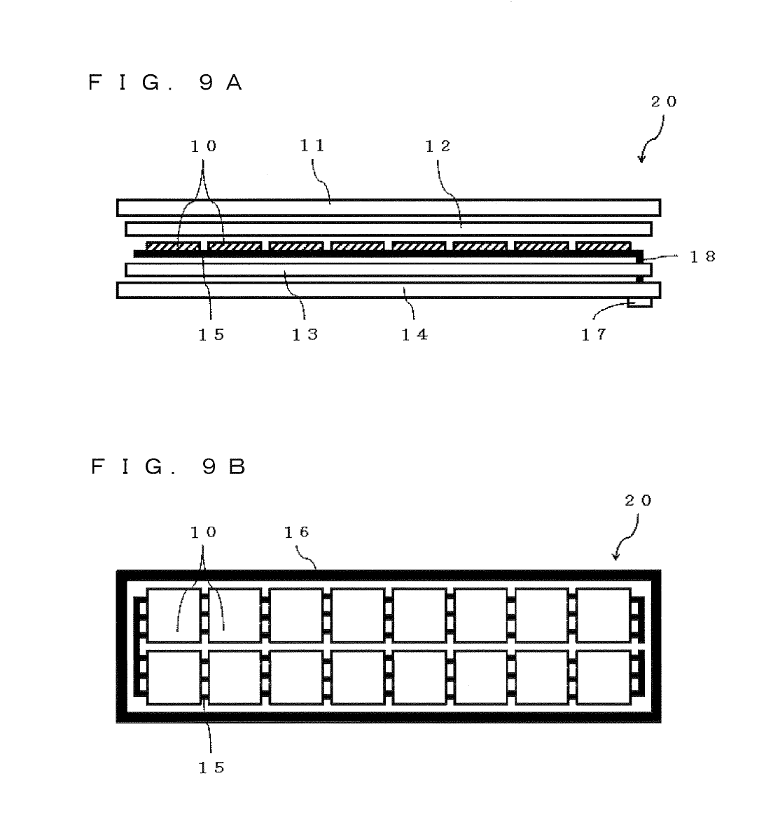

Next, a solar cell element 50 according to a fourth embodiment of the present invention will be described below with reference to FIG. 8. A description of the same configuration as that of the first embodiment will be omitted.

The embodiment is different from the first embodiment in the shape of the second electrode 5. Specifically, in the first embodiment, the connection part 5d is connected to the second output taking part 5a through the second collection part 5c. On the other hand, in the embodiment, as shown in FIG. 8, the connection part 5d is directly connected to the second output taking part 5a. In the embodiment, as shown in FIG. 8, the second collection parts 5c are formed on the first collection parts 5b located between the taking areas 4c2 in the alignment direction of the conduction parts 4b (direction parallel to the reference side BS). In the above configuration, carriers can be efficiently collected.

### Solar Cell Module

### Fifth Embodiment

The solar cell element 10 according to the first embodiment described above can be singularly used. However, the solar cell element 10 is also used as an element configuring a solar cell module. More specifically, the solar cell element 10 is arranged to be adjacent to the plurality of solar cell elements 10 each including the same structure. Furthermore, the solar cell elements 10 can be connected in series with each other to configure a module. A solar cell module 20 according to the fifth embodiment of the present invention will be described below with reference to FIG. 9 to FIG. 11.

The solar cell module 20 includes the plurality of solar cell elements 10 according to the first embodiment arranged to be adjacent to each other and the wiring material 15 that electrically connects the adjacent solar cell elements 10 to each other.

The solar cell module 20, as shown in FIG. 9(a), furthermore, includes a transparent member 11, a surface-side filler 12, a rear-side filler 13, and a rear-surface protective material 14. The transparent member 11 is arranged on the first surface 1F side of the solar cell element 10 to have a function of protecting the first surface 1F, and comprised of glass or the like, for example. The surface-side filler 12 is arranged between the first surface 1F of the solar cell element 10 and the transparent member 11 to have a function of sealing the solar cell element 10, and is comprised of a transparent ethylene vinyl acetate copolymer (EVA) or the like, for example. The rear-side filler 13 is arranged on the second surface 1S side of the solar cell element 10 to have a function of sealing the solar cell element 10, and is comprised of EVA or the like, for example. The rear-surface protective material 14 has a function of protecting the second surface 1S side of the solar cell element 10, and is comprised of, for example, a material obtained by sandwiching polyethylene terephthalate (PET) with a polyvinyl fluoride resin (PVF) or sandwiching a metal foil with PVF.

The plurality of solar cell elements 10, as shown in FIG. 9(b), are arranged such that the adjacent solar cell elements 10 are connected in series with the wiring material 15 having a function of a connector material.

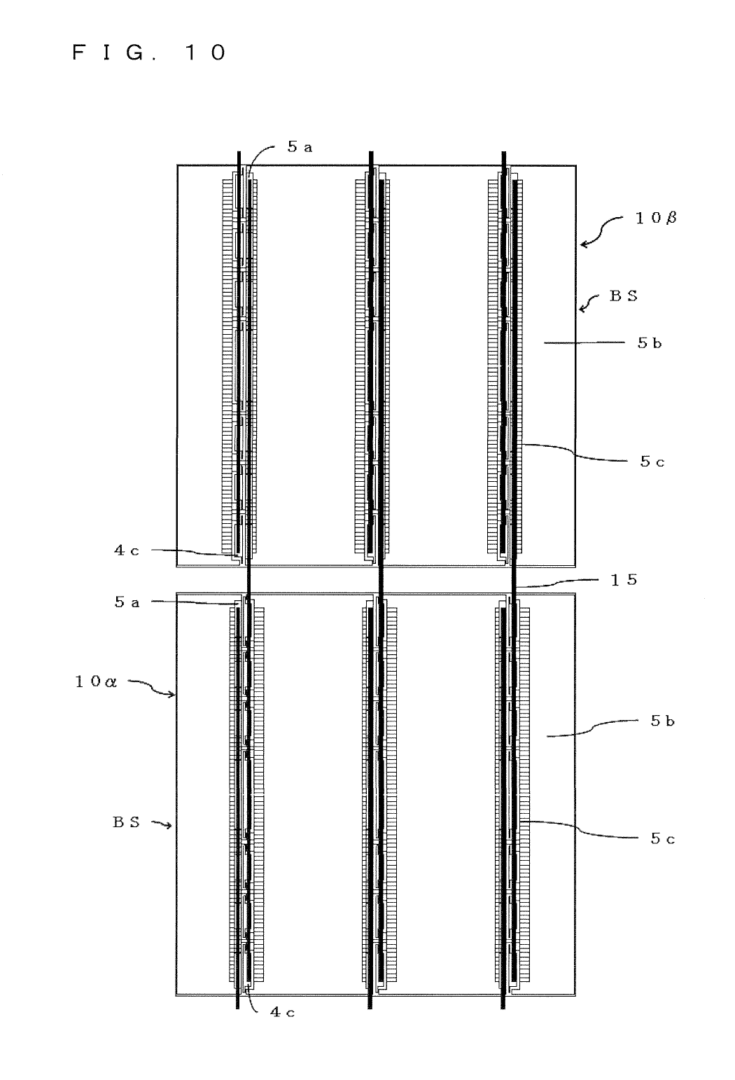

FIG. 10 is a diagram showing details about a manner of connection between solar cell elements 10 by the wiring material 15 in the solar cell module 20.

FIG. 9(a) shows only a schematic section. However, in the solar cell module 20, as shown in FIG. 10, the first output taking part 4c of one of the adjacent solar cell elements 10 and the second output taking part 5a of the other of the solar cell elements 10 are connected to each other by the long-sheet (linear) wiring material 15. In the embodiment, the connections are performed at 3 positions that are equal to the number of columns of the conduction parts 4b.

For descriptive convenience, in the following description, in FIG. 10, of the two solar cell elements 10 connected by the wiring material 15, the solar cell element 10 including the wiring material 15 connected to the first output taking part 4c is called a first solar cell element 10a, and the solar cell element 10 including the wiring material 15 connected to the second output taking part 5a is called a second solar cell element 10β.

As shown in FIG. 10, in the solar cell module 20, the first solar cell element 10a and the second solar cell element 10β are arranged such that the reference sides BS thereof are parallel to each other, are not on the same straight line, and are rotationally symmetrical to each other (more specifically, point symmetry). In this manner, all the first output taking parts 4c and all the second output taking parts 5a located on the straight line (straight line parallel to the reference side BS) are connected to each other by one wiring material 15. In this case, relative positional relationships between the first output taking parts 4c and the plurality of second output taking parts 5a connected by one wiring material 15 are equivalent to each other. That is, all combinations between the plurality of first output taking parts 4c and the plurality of second output taking parts 5a are translationally symmetrical to each other. For this reason, as the wiring materials 15 used to connect the combinations between the first output taking parts 4c and the second output taking parts 5a, the wiring materials 15 each having the same shape can be used.

As the wiring material 15, for example, a material obtained by cutting a belt-like copper foil including the entire surface of which is covered with a solder material with a predetermined length in the longitudinal direction can be used. When the wiring material 15 covered with the solder material is used, the first output taking part 4c and the second output taking part 5a of the solar cell elements 10 are soldered by using hot air, a soldering copper, or the like or by using a reflow furnace or the like. The wiring material 15, for example, can be set to about 0.1 to 0.4 mm in thickness and about 2 mm in width.

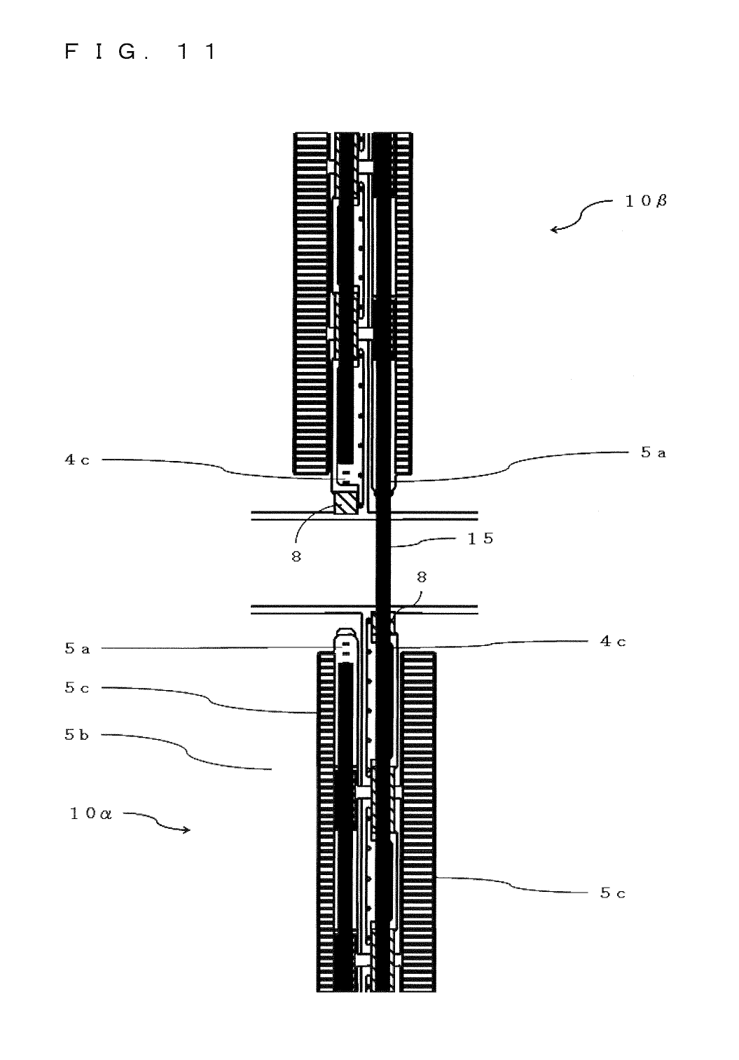

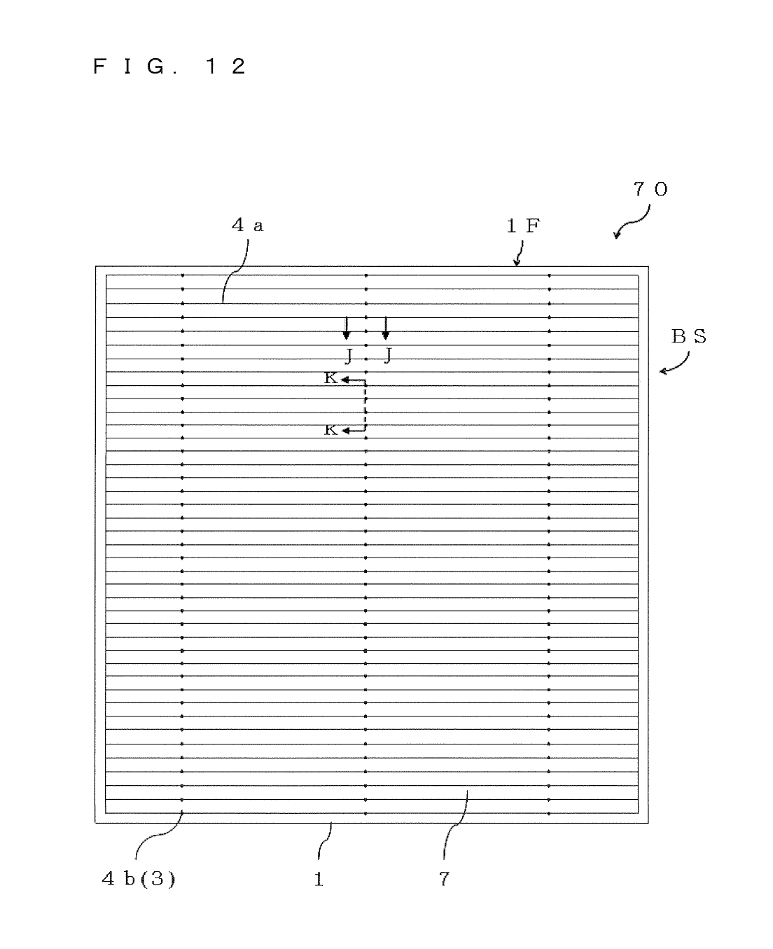

In the embodiment, as shown in FIG. 11, the solar cell module 20 comprises an insulating layer 8. The insulating layer 8 is formed in an area except for the first output taking part 4c on the alignment of the first output taking parts 4c, and is comprised of an oxide film, a resin, an insulating tape, or the like. With the above configuration, short-circuits caused when the wiring material 15 is in contact with the second electrode 5 and the like can be reduced. At this time, the insulating layer 8 may be formed to cover a p-n isolation area. In the embodiment, the insulating layer 8 is arranged on the solar cell element 10. However, the insulating layer 8 may be arranged on the wiring material 15.

The wiring material 15 may have a shape separated from the semiconductor substrate 1 in a non-contact area that is an area except for a contact area with the plurality of first output taking parts 4c and the plurality of second output taking parts 5a. For example, the wiring material 15 may have an uneven shape including a convex portion that is far from the non-contact area. In this case, since the second electrode 5 and the wiring material 15 are not in contact with each other between the first output taking parts 4c, short-circuits can be reduced.

As the rear-surface protective material 14, a white material or the like having a high reflectance can be used. In this manner, light irradiated on between the solar cell elements 10 is irregularly reflected by the rear-surface protective material 14 to illuminate the solar cell elements 10. As a result, an amount of light received in the solar cell element 10 can be more increased. As the material of the rear-surface protective material 14, for example, white PET or the like can be used.

### Sixth Embodiment

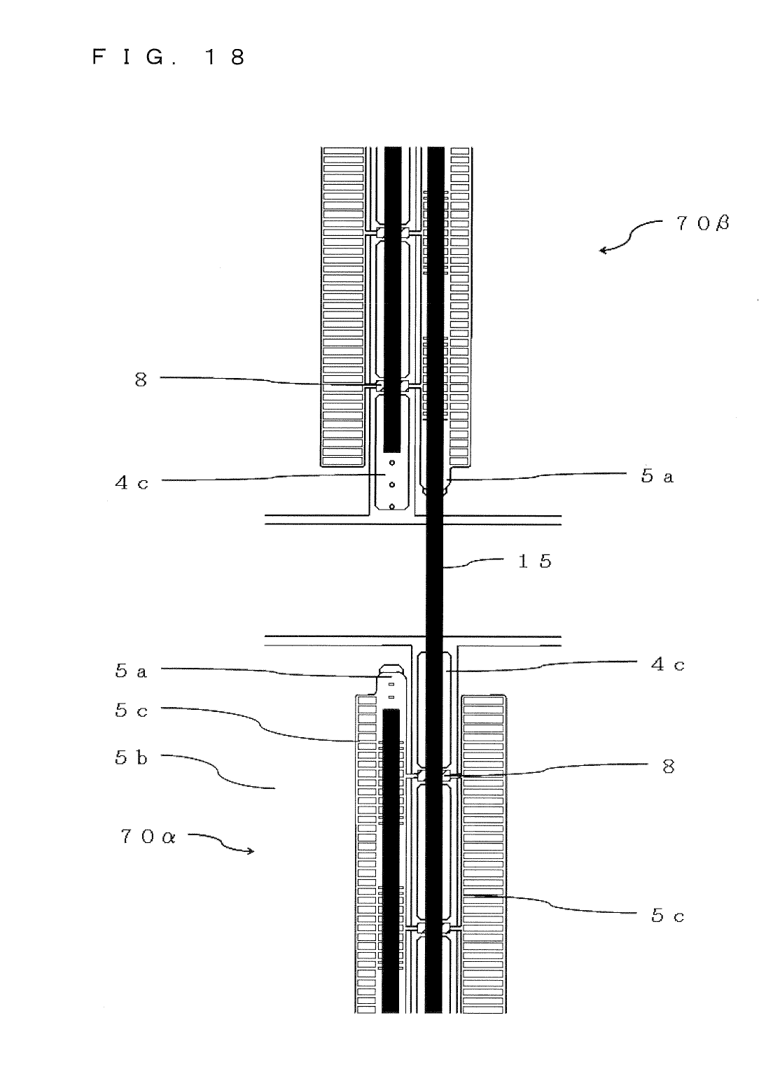

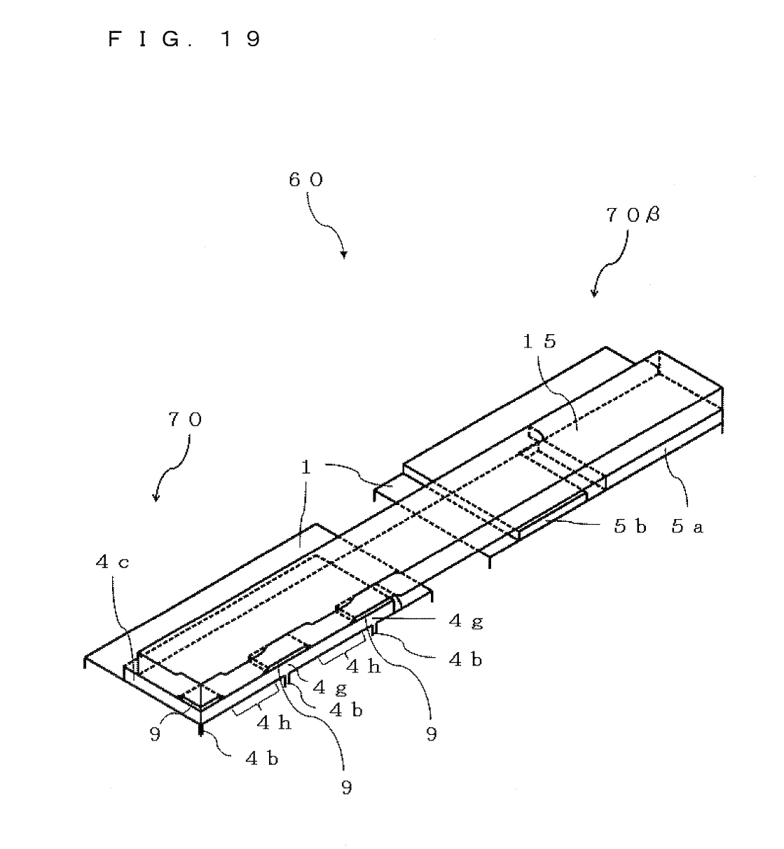

Next, a solar cell module 60 according to the embodiment will be described below with reference to FIG. 12 to FIG. 20. A description of the same configuration as that of the solar cell module 20 according to the fifth embodiment will be omitted.

First, a solar cell element 70 in the solar cell module 60 according to the sixth embodiment will be described below with reference to FIG. 12 to FIG. 15. A description of the same configuration as that of the solar cell element 10 according to the first embodiment will be omitted.

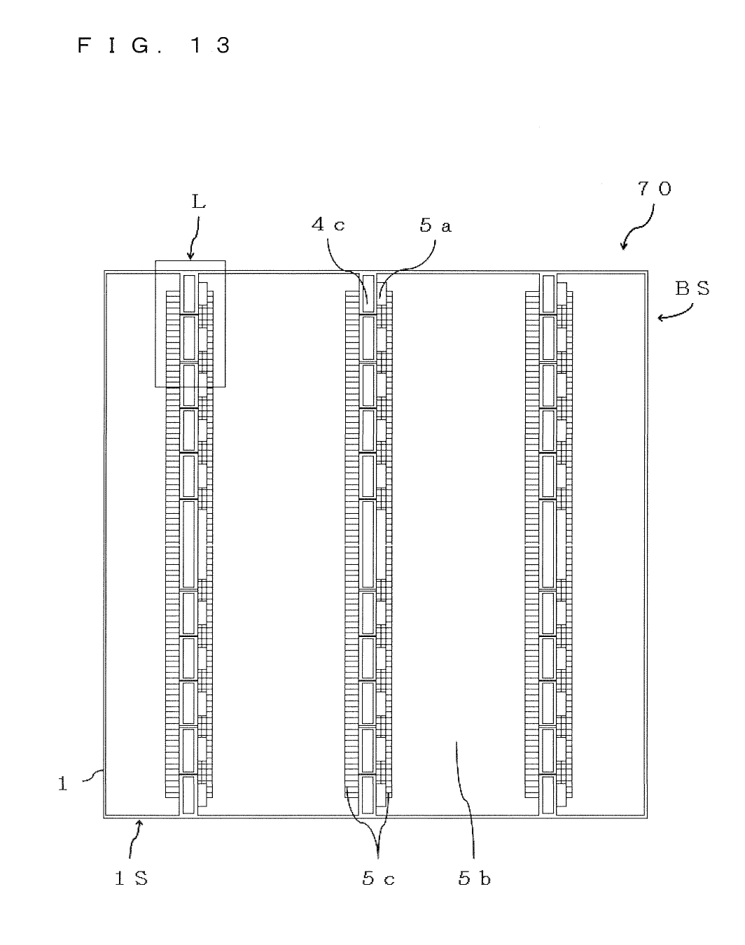

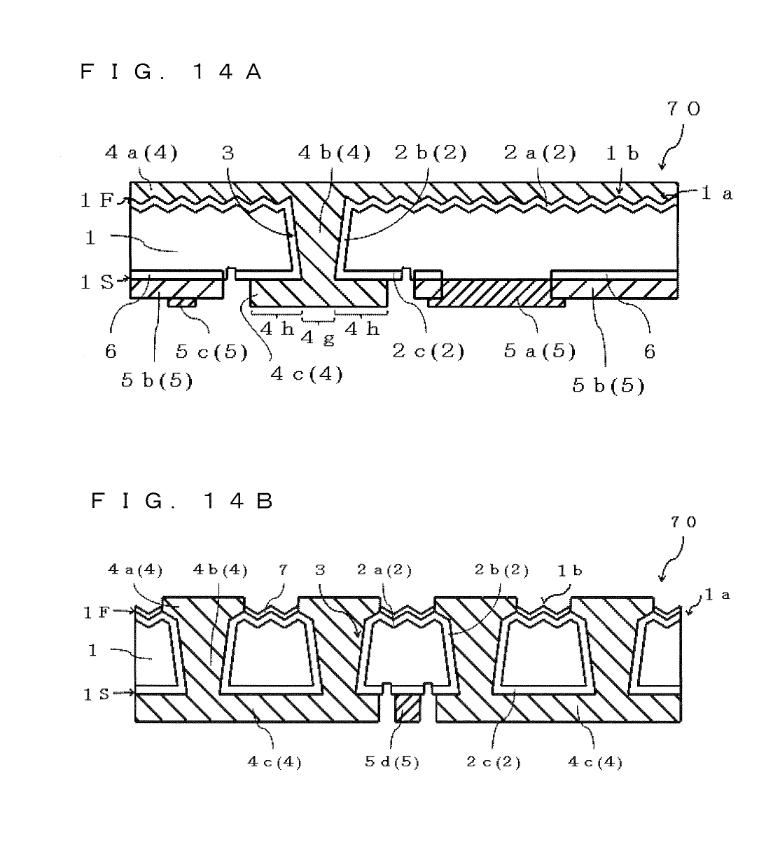

The solar cell element 70 according to the embodiment is different from the solar cell elements 10 according to the first embodiment in the shape of the first output taking part 4c. The shape of the first output taking part 4c according to the embodiment will be described below in detail with reference to FIG. 13 to FIG. 15.

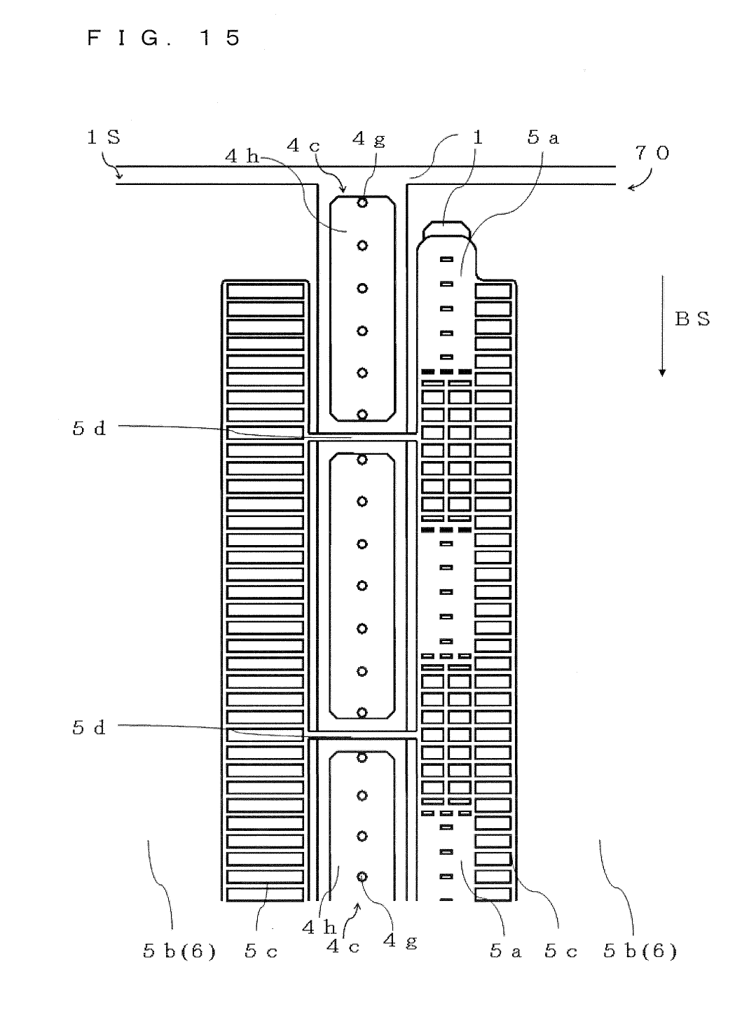

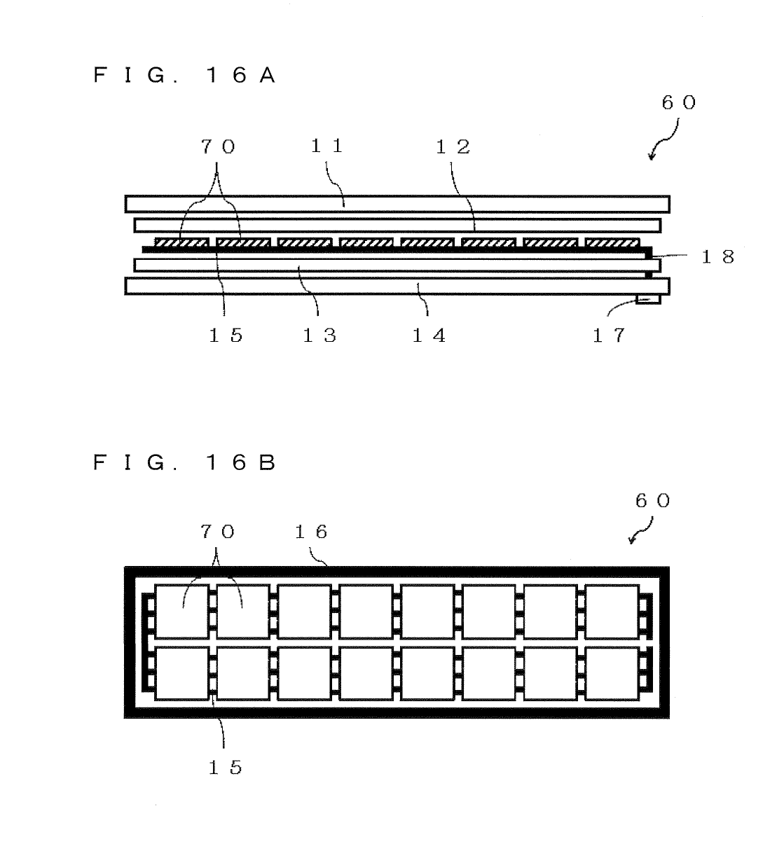

The solar cell element 70, as shown in FIG. 15, one of the first output taking parts 4c is connected to the plurality of conduction parts 4b. Each of the first output taking parts 4c has a long-sheet shape having a longitudinal direction in the alignment direction of the first output taking parts 4c. The first output taking part 4c, as shown in FIG. 14 and FIG. 15, includes a first area 4g and a second area 4h.

The first area 4g is an area located on the conduction part 4b exposed on the second surface 1S of the semiconductor substrate 1, and the second area 4h is an area located on the second surface 1S of the semiconductor substrate 1 except for on the conduction part 4b. Specifically, the first area 4g indicates an area overlapping the conduction part 4b and forms an almost circular shape as shown in FIG. 15 when the semiconductor substrate 1 is viewed from the second surface 1S. The second area 4h indicates an area except for the first area 4g on the first output taking part 4c.

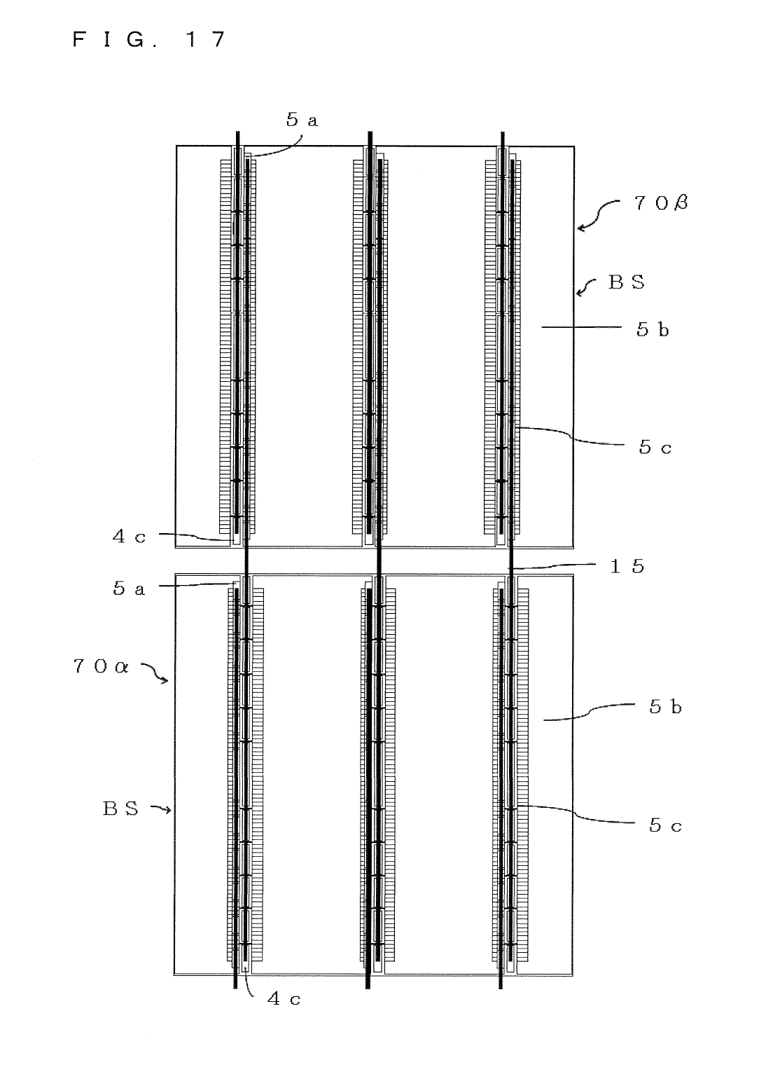

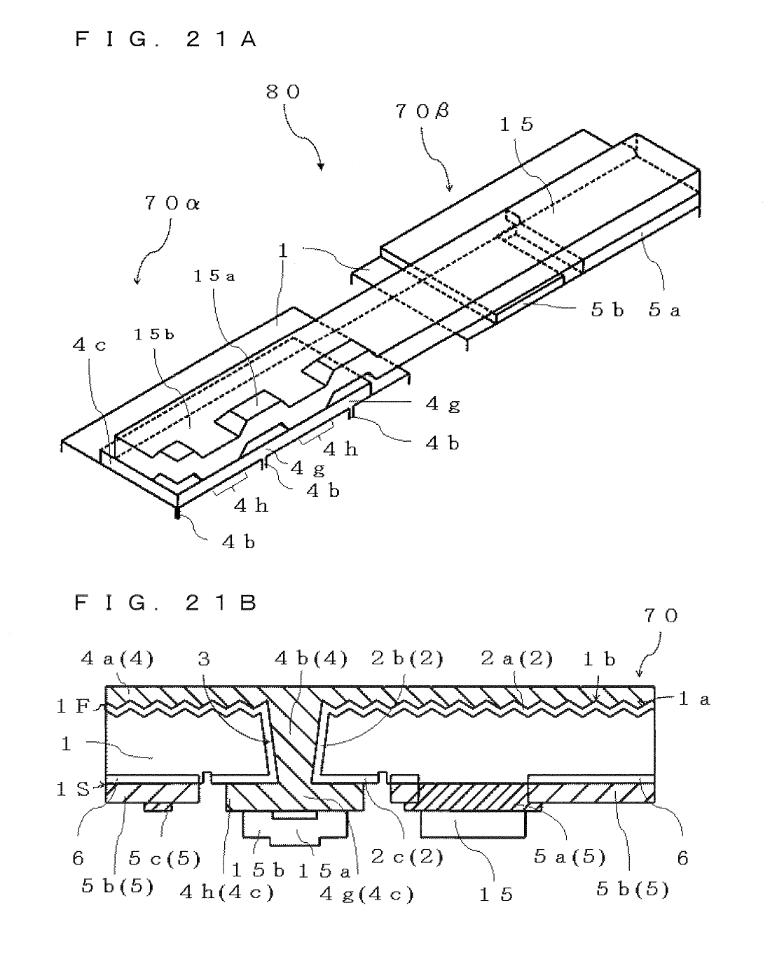

Next, the solar cell module 60 using the solar cell element 70 will be described below in detail with reference to FIG. 16 to FIG. 20. FIG. 20(b) is a partially enlarged sectional view corresponding to FIG. 14(a) in the solar cell module 60. A description of the same configuration as that of the solar cell module 20 according to the fifth embodiment will be omitted.

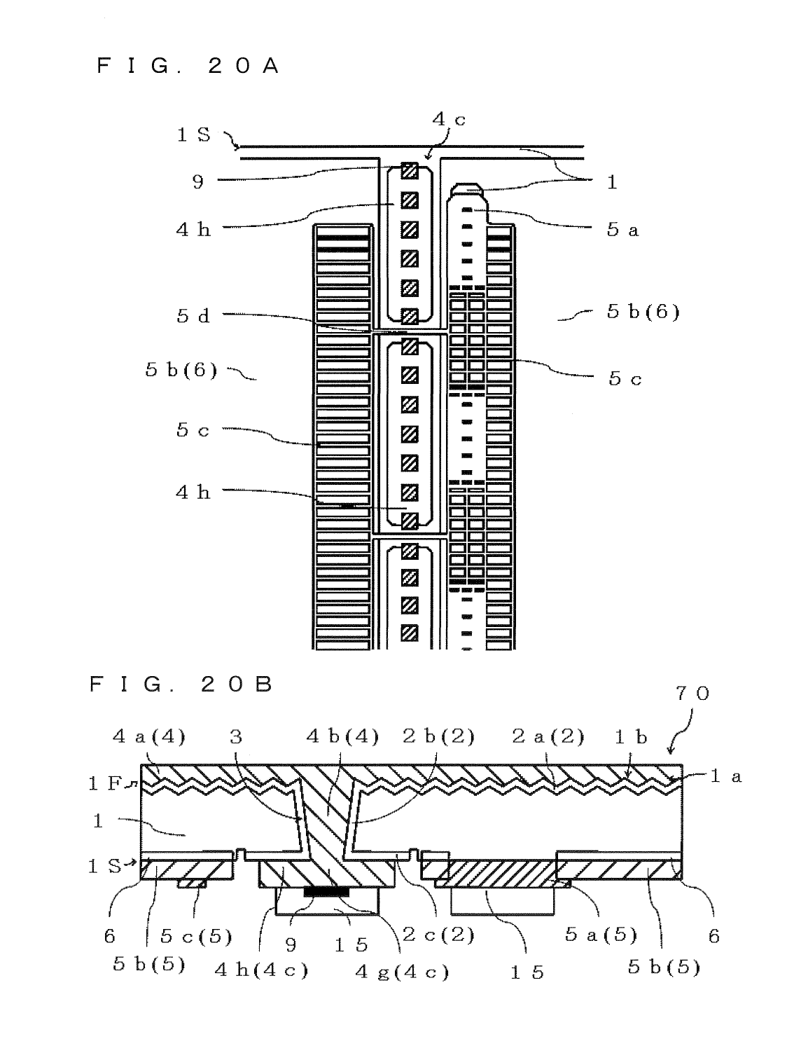

The solar cell module 60 according to the embodiment is different from the solar cell module 20 in a mode of connection between the first output taking part 4c and the wiring material 15. Specifically, in the embodiment, as shown in FIG. 19, the wiring material 15 is arranged to be located immediately above the first area 4g of the first output taking part 4c of a first solar cell element 70α. The wiring material 15 arranged as described above is connected to only the second area 4h by bonding. More specifically, the wiring material 15 is partially bonded to at least a part of the second area 4h without being bonded to the first area 4g of the first output taking part 4c of the first solar cell element 70α.

In the above configuration, since the first area 4g located on the conduction part 4b is not bonded to the wiring material 15, the conduction part 4b is not easily influenced by expansion and contraction of the wiring material 15 caused by daily temperature cycling. As a result, damage such as cracks in the conduction part 4b can be reduced, and long-term reliability can be improved. Since the wiring material 15 can be arranged along the longitudinal direction of the first output taking part 4c such that the wiring material 15 is located immediately above the first area 4g of the first output taking part 4c, the electrode on the second surface 1S side of the solar cell element can be formed by a simple shape. As a result, an ohmic loss or the like of the solar cell module caused by a complex electrode shape on the second surface 1S can be reduced.

The embodiment, as a concrete embodiment in which the wiring material 15 described above is bonded to only the second area 4h of the first output taking part 4c, includes the following mode.

As shown in FIG. 19 and FIG. 20, the solar cell module 60 includes the protective layer 9 comprised of a solder resist or the like between the wiring material 15 and the first area 4g of the first output taking parts 4c. According to the method, even though the solder of the wiring material 15 is melted to connect the wiring material 15 and the first output taking parts 4c to each other, the wiring material 15 is not bonded to the protective layer 9 located on the first area 4g but is bonded to the second area 4h.

As long as the protective layer 9 can suppress bonding between the first area 4g and the wiring material 15, the protective layer 9 is not limited, and may be comprised of an insulating material or a conductive material. For example, the material of the protective layer 9, a metal, for example, aluminum having low wettability to a solder can be used.

When aluminum is used as the protective layer 9 and the first collection parts 5b, after the first output taking part 4c is formed in advance, the protective layer 9 and the first collection part 5b are formed in the same step to make it possible to improve productivity. In this manner, the conductive protective layer 9 is formed, and the wiring material 15 and the protective layer 9 are brought into contact with each other to make it possible to electrically connect the first area 4g to the wiring material 15 through the protective layer 9.

When materials such as polyimide having low wettability to a solder are used as the protective layer 9 and the insulating layer 8, the protective layer 9 and the insulating layer 8 are formed in the same step to make it possible to improve productivity.

In the embodiment, although described a case when the protective layer 9 is arranged on the solar cell element 70 side in the solar cell module 60, specifically, on the first output taking part 4c side, the protective layer 9 may be arranged on the wiring material 15 side in advance. More specifically, by using the wiring material 15 including the protective layer 9, the plurality of solar cell elements 70 may be connected.

In the embodiment, the protective layer 9 is formed to cover not only the first area 4g but also, as shown in FIG. 19 and FIG. 20(b), a part of the second area 4h located on the peripheral portion of the first area 4g. Specifically, the first area 4g, as shown in FIG. 15, may have an almost circular shape when viewed from the second surface 1S side. On the other hand, the protective layer 9, as shown in FIG. 20(a), has an almost rectangular shape when viewed from the second surface 1S side. Even in the above configuration, the wiring material 15 can be bonded to the second area 4h, not the first area 4g.

The protective layer 9 may be formed by, for example, applying and heat-treating an aluminum paste, or may be formed by applying and hardening an ultraviolet curing or thermosetting solder resist.

### Seventh Embodiment

Next, a solar cell module 80 according to the seventh embodiment of the present invention will be described below with reference to FIG. 21. FIG. 21(b) is a partially enlarged sectional view corresponding to FIG. 14(a) in the solar cell module 80. A description of the same configuration as that of the solar cell module 60 according to the sixth embodiment will be omitted.

The solar cell module 80 according to the embodiment is different from the solar cell module 60 in the shape of the wiring material 15. Specifically, the wiring material 15 is located on the first area 4g of the first output taking part 4c and arranged to be separated from the first area 4g. More specifically, as shown in FIGS. 21(a) and (b), the wiring material 15 includes a bent portion 15a and a flat portion 15b.

The bent portion 15a is a part of the wiring material 15 located immediately above the first area 4g and has a convex shape. The flat portion 15b is a part of the wiring material 15 except for the bent portion 15a. As shown in FIGS. 21(a) and (b), the bent portion 15a projects in a direction away from the flat portion 15b, i.e., the second surface 1S.

By the wiring material 15 having the above shape, the first area 4g of the first output taking part 4c can be prevented from being bonded to the wiring material 15. At this time, in the embodiment, as shown in FIG. 21, a convex portion (bent portion 15a) is formed in only the first area 4g or only the first area 4g and the peripheral portion thereof. For this reason, contact between the first area 4g and the rear-side filler 13 can be reduced, and moisture got into the solar cell module can be suppressed from reaching the conduction part 4b.

Also in the embodiment, the wiring material 15 is arranged to separate the wiring material 15 from the first area 4g of the first output taking part 4c, and, as in the embodiment described above, the protective layer 9 may be arranged on the first area 4g.

### Eighth Embodiment

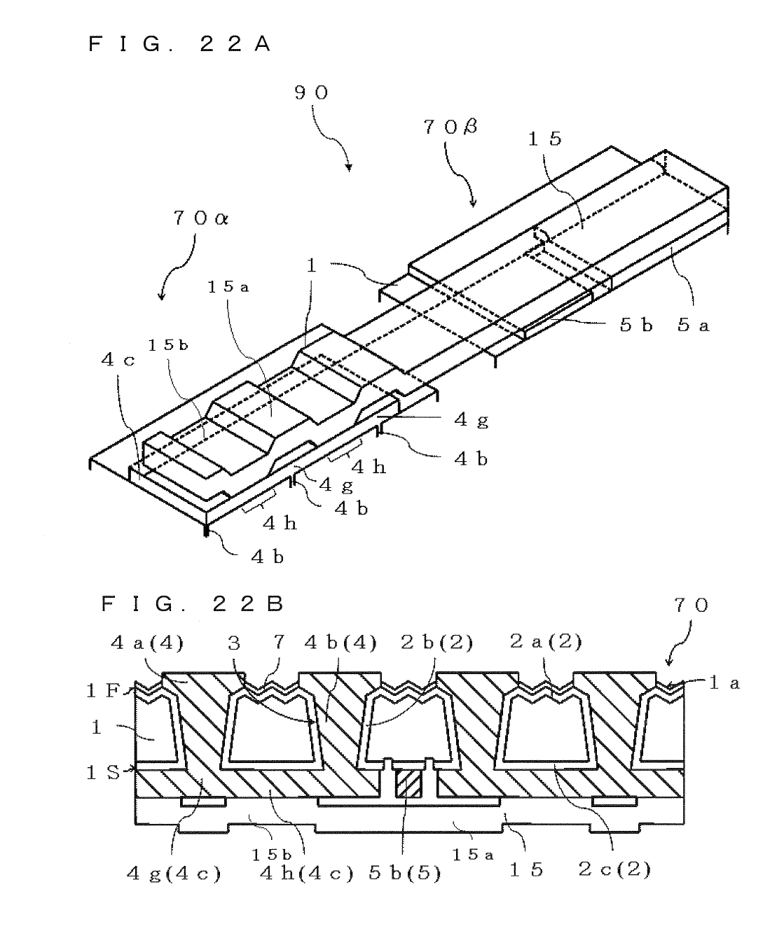

Next, a solar cell module 90 according to an eighth embodiment of the present invention will be described below with reference to FIG. 22. FIG. 22(b) is a partially enlarged sectional view corresponding to FIG. 14(b) in the solar cell module 90. A description of the same configuration as that of the solar cell module 60 according to the sixth embodiment will be omitted.

The solar cell module 90 according to the embodiment is different from the solar cell module 80 in the shape of the wiring material 15. Specifically, as shown in FIGS. 22(a) and (b), the module is different from the solar cell module 80 in the shape of the bent portion 15a. More specifically. As shown in FIGS. 22(a) and (b), convex portions (bent portion 15a) are formed in the whole region of a width direction of the wiring material 15 where the first areas 4g are located. The width direction of the wiring material 15 mentioned here, for example, is a direction orthogonal to an alignment direction of the first output taking parts 4c.

In the sixth to eighth embodiments, the mode of connection between the wiring material 15 and the first output taking part 4c has been described. Specifically, the configuration including the protective layer 9 has been described as the sixth embodiment, and a configuration including the wiring material 15 including the bent portion 15a and the flat portion 15b has been described as the seventh and eighth embodiments. The configuration in which the wiring material 15 is separated from the first area 4g and brought into contact with the second area 4h is not limited to the above. For example, when the wiring material 15 and the first output taking part 4c are bonded to each other by the conductive adhesive, the conductive adhesive is placed only in the second area 4h to make it possible to bond the wiring material 15 in the second area 4h without bonding the first area 4g and the wiring material 15 to each other.

### Method of Manufacturing Solar Cell Element

Next, a method of manufacturing a solar cell element will be described below. Specifically, a method of manufacturing the solar cell element 10 will be described.

### Step of Preparing Semiconductor Substrate

First, the semiconductor substrate 1 that exhibits a p-type conductivity type is prepared.

When a single-crystal silicon substrate is used as the semiconductor substrate 1, a single-crystal ingot is sliced into a predetermined thickness so as to make it possible to obtain the semiconductor substrate 1. A single-crystal silicon ingot manufactured by the known manufacturing method such as an FZ method or a CZ method can be used. When the poly-crystal silicon substrate is used as the semiconductor substrate 1, the semiconductor substrate 1 can be obtained by slicing a poly-crystal silicon ingot into a predetermined thickness. A poly-crystal silicon ingot manufacturing by the known manufacturing method such as a casting method, an in-cast solidification method, or the like can be used.

The following explanation will be made by exemplifying a case in which a crystalline silicon substrate that exhibits a p-type conductivity type and in which B (boron) or Ga (gallium) is doped as a dopant element at about 1×10¹⁵ to 1×10¹⁷ atoms/cm³ is used as the semiconductor substrate 1.

A mechanical damaged layer or a contaminated layer formed on the surface layer of the semiconductor substrate 1 by cutting (slicing) is removed in advance. For example, the surface parts on a surface side and a rear surface side of the semiconductor substrate 1 may be etched in about 10 to 20 μm with NaOH, KOH, or a liquid mixture of a hydrofluoric acid and a nitric acid, and then cleaned with pure water or the like. In this manner, an organic component and a metal component is removed in advance.

### Step of Forming Through Hole

Next, the through hole 3 is formed between the first surface 1F and the second surface 1S of the semiconductor substrate 1.

The through hole 3 can be formed by using a mechanical drill, a water jet, a laser machining device, or the like. The through hole 3 is formed such that the semiconductor substrate 1 is processed from the second surface 1S side to the first surface 1F side without damaging the first surface 1F serving as a light-receiving surface. However, when the semiconductor substrate 1 is less damaged by processing, processing may be performed from the first surface 1F to the second surface 15.

### Step of Forming Texture Structure

Next, a texture structure 1a including a small projection (convex portion) 1b is formed on a light-receiving surface side of the semiconductor substrate 1 in which the through hole 3 is formed. The texture structure 1a, as described above, is to effectively reduce an optical reflectance.

As a method of forming the texture structure 1a, a wet etching method with an alkaline aqueous solution such as NaOH or KOH or a dry etching method using an etching gas having the property of etching silicon serving as a material of the semiconductor substrate 1 can be used.

### Step of Forming Opposite Conductivity Type Layer

Next, the opposite conductivity type layer 2 is formed. More specifically, the first layer 2a is formed on the first surface 1F of the semiconductor substrate 1, the second layer 2b is formed on the internal surface of the through hole 3, and the third layer 2c is formed on the second surface 1S.

When a crystalline silicon substrate that exhibits a p-type conductivity type is used as the semiconductor substrate 1, the opposite conductivity type layer 2 exhibits an n type. As an n-doping element to form the opposite conductivity type layer 2, P (phosphorous) can be used.

The opposite conductivity type layer 2 can be formed by using, for example, the following method. As the first method, an applying thermal diffusion method that applies a P₂O₅ paste on a forming target position of the opposite conductivity type layer 2 on the semiconductor substrate 1 to perform thermal diffusion is known. As a second method, a gas-phase thermal diffusion method that diffuses a POCl₃ (phosphorous oxychloride) gas as a diffusion source into a forming target position is known. As a third method, an ion implantation method that directly diffuses phosphorous by causing an ion beam to be incident on a forming target position is used. By using the gas-phase diffusion method, on the forming target positions on both the major surfaces of the semiconductor substrate 1 and the internal surface of the through hole 3, the opposite conductivity type layers 2 can be formed in the same step.

In the condition in which a diffusion area is also formed at a position except for the forming target position, after an anti-diffusion layer is formed at the position in advance, and the opposite conductivity type layer 2 may be formed. In this manner, diffusion in a position except for the forming target position can be reduced. A diffusion region formed at a position except for the forming target position may be removed by etching without forming the anti-diffusion layer.

After the opposite conductivity type layer 2 is formed, as will be described later, when the semiconductor layer 6 is formed by an aluminum paste, aluminum serving as a p-type dopant element can be diffused in a sufficient depth at a sufficient concentration. For this reason, in this case, the presence of a shallow diffusion area formed in advance can be neglected. More specifically, in this case, the opposite conductivity type layer 2 that is present at a forming target position of the semiconductor layer 6 need not be specially removed.

With respect to a circumference of the area in which the first electrode 4 is formed and the peripheral portion of the second surface 1S of the semiconductor substrate 1, p-n isolation may be performed by the known method such as laser irradiation.

### Step of Forming Antireflective Layer

Next, the antireflective layer 7 may be formed on the first layer 2a.

As a method of forming the antireflective layer 7, a PECVD method, a vapor deposition method, a sputtering method, or the like can be used. For example, when the antireflective layer 7 comprised of an SiNx film is to be formed by the PECVD method, 500° C. is set in a reaction chamber, and the antireflective layer 7 is formed by producing a plasma by glow discharge decomposition using a gas mixture of silane (Si₃H₄) and ammonia (NH₃) that are thinned with nitrogen (N₂). The antireflective layer 7 may also be formed on the second layer 2b.

### Step of Forming Semiconductor Layer

Next, the semiconductor layer 6 is formed on the second surface 1S of the semiconductor substrate 1.

When boron is used as a dopant element, formation can be performed at a temperature of about 800 to 1100° C. by a thermal diffusion method using BBr₃ (boron tribromide) as a diffusion source. In this case, prior to the formation of the semiconductor layer 6, on an area except for the forming target position of the semiconductor layer 6, for example, on the opposite conductivity type layer 2 or the like that has been formed, an anti-diffusion layer comprised of an oxide film or the like may be formed, and then removed after the semiconductor layer 6 is formed.

When aluminum is used as a dopant element, after an aluminum paste containing aluminum powder, an organic vehicle, and the like is applied to the second surface 1S of the semiconductor substrate 1 by a printing method and heat-treated (baked) at a temperature of about 700 to 850° C. to diffuse aluminum toward the semiconductor substrate 1 to make it possible to form the semiconductor layer 6. In this case, the semiconductor layer 6 serving as a desired diffusion area can be formed on only the second surface 1S serving as a printed surface of the aluminum paste. Furthermore, a layer comprised of aluminum formed on the second surface 1S after the firing can be directly used as the first collection part 5b without being removed.

### Method of Forming Electrode

Next, light-receiving surface electrode parts (main electrode part 4a and pad electrode part 4e) of the first electrode 4 and the conduction part 4b are formed.

The light-receiving surface electrode part and the conduction part 4b are formed by using an applying method, for example. Specifically, a conductive paste is applied to the first surface 1F of the semiconductor substrate 1 in a forming pattern for the light-receiving surface electrode part shown in FIG. 1 to form an applied film. The formed applied film is fired at a maximum temperature of 500 to 850° C. for several ten seconds to several ten minutes to make it possible to form the light-receiving surface electrode part and the conduction part 4b. As the conductive paste used here, for example, a paste obtained by adding 10 to 30 parts by mass of an organic vehicle and 0.1 to 10 parts by mass of glass frit to 100 parts by mass of metal powder comprised of silver or the like can be used.

In this case, when the conductive paste is filled in the through hole 3 during the conductive paste is applied, in the same step as the step of forming a light-receiving surface electrode part, the conduction part 4b can also be formed. However, the conductive paste need not be sufficiently filled in the through hole 3 when the conductive paste is applied to the first surface 1F. This is because, as will be described later, the conductive paste is applied from the second surface 1S side also when the first output taking part 4c is formed, and, at this time, the conductive paste is also filled in the through hole 3 again and then fired.

After the conductive paste is applied, prior to firing, a solvent in the applied film may be evaporated at a predetermined temperature to dry the applied film. The light-receiving surface electrode part (including the main electrode parts 4a) and the conduction part 4b may be formed by separately performing applying and firing. Specifically, the conductive paste is filled in the through hole 3 in advance and dried. Thereafter, as in the above case, the conductive paste may be applied in a pattern of the light-receiving surface electrode part (including the main electrode part 4a) shown in FIG. 1 and then fired.

As described above, when the antireflective layer 7 is formed prior to the formation of the light-receiving surface electrode part (including the main electrode part 4a), the light-receiving surface electrode part may be formed in a patterned area, or the light-receiving surface electrode part may be formed by a fire-through method.

On the other hand, after the light-receiving surface electrode part is formed, the antireflective layer 7 may be formed. In this case, the antireflective layer 7 need not be patterned, and the fire-through method need not be used. For this reason, forming conditions for the light-receiving surface electrode part become moderate. In the steps described above, for example, even though firing is not performed at a high temperature of about 800° C., the light-receiving surface electrode part can be formed. As a result, heat damage to the semiconductor substrate 1 can be reduced.

Subsequently, on the second surface 1S of the semiconductor substrate 1, the first collection part 5b is formed.

The first collection parts 5b can also be formed by the applying method. Specifically, a conductive paste is applied to the second surface 1S of the semiconductor substrate 1 in a forming pattern of the first collection part 5b shown in FIG. 2 to form an applied film. The formed applied film is fired at a maximum temperature of 500 to 850° C. for several ten seconds to several ten minutes to make it possible to form the first collection part 5b. As the conductive paste used here, for example, a paste obtained by adding 10 to 30 parts by mass of an organic vehicle and 0.1 to 5 parts by mass of glass frit to 100 parts by mass of metal powder comprised of aluminum, silver, or the like can be used. When an aluminum paste is used as the conductive paste, the semiconductor layer 6 and the first collection part 5b can be formed in the same step.

Furthermore, on the second surface 1S of the semiconductor substrate 1, the first output taking part 4c, the second output taking part 5a, the second collection part 5c, and the connection part 5d are formed.

The first output taking part 4c, the second output taking part 5a, the second collection part 5c, and the connection part 5d can be formed in one step by using an applying method, for example. Specifically, a conductive paste is applied to the second surface 1S of the semiconductor substrate 1 in an electrode pattern as shown in FIG. 2 or FIG. 4 to form an applied film. The formation can be performed by firing the formed applied film at a maximum temperature of 500 to 850° C. for several ten seconds to several ten minutes. As the conductive paste used here, for example, a paste obtained by adding 10 to 30 parts by mass of an organic vehicle and 0.1 to 10 parts by mass of glass frit to 100 parts by mass of metal powder comprised of silver or the like can be used.

The respective configurations may be formed in different steps, and may be formed by using conductive pastes having different compositions. When the semiconductor layer 6 and the first collection part 5b are formed in one step by using an aluminum paste, a part of the second output taking part 5a is formed on the third layer 2c without causing a specific problem.

The solar cell element 10 according to the embodiment can be manufactured by the above procedures.

As needed, a solder area (not shown) may be formed on the first output taking part 4c and the second output taking part 5a by a solder dip process.

The insulating layer 8, for example, may be formed by using a thin-film forming technique such as a CVD method, may be formed by applying and firing an insulating paste comprised of a resin paste, or may be formed by sticking a commercially available insulating tape. When the insulating paste is fired, the formation can be performed in the same step when the electrode is formed.

### Method of Manufacturing Solar Cell Module

Next, a method of manufacturing the solar cell module 20 by using the solar cell element 10 formed as described above will be described below.

First, the wiring material 15 is manufactured in advance by cutting a material obtained by coating the entire surface of a copper foil having a thickness of about 0.1 to 0.4 mm and a width of about 2 mm with a solder material into a predetermined length in a longitudinal direction.

Then, as shown in FIG. 9, the plurality of solar cell elements 10 are placed at predetermined intervals to cause the second surfaces 1S to face upward, and the wiring material 15 is brought into contact with between the first output taking part 4c of the first solar cell element 10α and the second output taking part 5a of the second solar cell element 10β from above. In this state, by using hot air or a soldering copper, or by using a reflow furnace, a solder on the surface of the wiring material 15 is melted to connect the wiring material 15 to the first output taking part 4c and the second output taking part 5a. According to the method, the adjacent solar cell elements 10 can be connected to each other at high productivity.

Thereafter, on the transparent member 11, the surface-side filler 12, the plurality of solar cell elements 10 connected to each other by the wiring material 15, the rear-side filler 13, and the rear-surface protective material 14 are sequentially laminated to manufacture a module base substance. The module base substances are integrated with each other by degassing, heating, and depressing to manufacture the solar cell module 20.

Then, as shown in FIG. 8(b), a frame 16 comprised of aluminum or the like is fitted on the outer periphery of the solar cell module 20 described above as needed. As shown in FIG. 8(a), of the plurality of solar cell elements 10 connected in series with each other, one ends of the first solar cell element 10 and the last solar cell element 10 are connected to a terminal box 17 that takes outputs outside by an output taking wire 18.

With the above procedures, the solar cell module 20 according to the embodiment can be obtained.

A solar cell module according to another embodiment can be manufactured by the same procedures as described above.

For example, the solar cell module 80 according to the seventh embodiment may be manufactured by using the wiring material 15 having the shape shown in FIGS. 21(a) and (b) in the above procedures. More specifically, as the wiring material 15 obtained by the cutting as described above, a material on which a convex shape is shaped at a predetermined position in advance may be used.

Then, as shown in FIG. 21, by the wiring material 15 having the above shape, a second area 2h of the first output taking part 4c of the first solar cell element 70α and the second output taking part 5a of a second solar cell element 70β may be connected to each other. At this time, the wiring material 15 is prevented from being bonded to the first area 4g of the first output taking part 4c of the first solar cell element 70α. According to the method, the adjacent solar cell elements 70 can be connected to each other at high productivity.

The solar cell module 90 according to the eighth embodiment can be manufactured by the same method as the manufacturing method of the solar cell module 80 according to the seventh embodiment.

In manufacturing of the solar cell module 60 according to the sixth embodiment, as described above, the wiring material 15 may be connected by using a cold-setting conductive adhesive. For example, when the conductive adhesive is heat-treated at about 150 to 250° C. after the wiring material 15 is brought into contact with on the second area 4h of the first output taking part 4c and the second output taking part 5a, the wiring material 15 can be connected to the first output taking part 4c and the second output taking part 5a. In this manner, the wiring material 15 is separated from the first area 4g of the first output taking part 4c and brought into contact with the second area 4h. As the conductive adhesive, for example, a conductive filler such as silver, nickel, or carbon containing an epoxy resin, a silicon resin, a polyimide resin, a polyurethane resin, or the like as a binder can be used.

The embodiments of the present invention have been described while illustrating the concrete configurations. However, the present invention is not limited to the embodiments, as a matter of course.

For example, in the solar cell element 10, as long as the alignment state is satisfied and the connection manner by the wiring material 15 can be realized, the first output taking part 4c and the second output taking part 5a may have shapes (for example, a trapezoidal shape, a circular shape, an oval shape, a semicircular shape, a sectorial shape, a composite shape thereof, or the like) different from the shapes described above.

When the solar cell element 10 is divided and used, a dividing position is set at a position near the connection part 5d to make it possible to reduce overlapping between the dividing position and the main electrode part 4a.

### DESCRIPTION OF SYMBOLS

1: Semiconductor substrate
2: Opposite conductivity type layer (diffusion layer)
2a: First layer
2b: Second layer
2c: Third layer
3: Through hole
4: First electrode
4a: Main electrode part
4a1: First electrode group
4a2: Second electrode group
4a3: Third electrode group
4b: Conduction part
4c: First output taking part
4c1: Conductor area
4c2: Taking area
4e: Pad electrode part
4f: Auxiliary electrode part
4g: First area
4h: Second area
5: Second electrode
5a: Second output taking part
5b: First collection part
5c: Second collection part
5d: Connection part
6: Semiconductor layer
7: Antireflective layer
8: Insulating layer
9: Protective layer
10, 30, 40, 50, 70: Solar cell element
11: Transparent substrate
12: Surface-side filler
13: Rear-side filler
14: Rear-surface protective material
15: Wiring material
16: Frame
17: Terminal box
18: Output taking wire
20, 60, 80, 90: Solar cell module

1. A solar cell element comprising:
a semiconductor substrate of once conductivity type that comprises a first surface and a second surface on a rear side of the first surface and exhibits one conductivity type;
a first electrode that comprises a plurality of main electrode parts each having a liner shape and located on the first surface, and a plurality of first output taking parts electrically connected to the plurality of main electrode parts and located on the second surface in a direction different from the longitudinal direction of the plurality of main electrode parts; and
a second electrode that comprises one pair of collection parts located on the second surface to sandwich the first output taking parts when the second surface is planarly viewed, and a connection part located on the second surface and electrically connecting the one pair of collection parts to each other;
wherein the plurality of main electrode parts comprise a first electrode group located at first intervals D in a direction orthogonal to the longitudinal direction of the plurality of main electrode parts and a second electrode group located at second intervals E in a direction orthogonal to the longitudinal direction of the plurality of main electrode parts,
in an alignment direction of the first output taking parts, a third interval F between the first electrode group and the second electrode group is larger than the first interval D and the second interval E, and
the connection part is located at a position corresponding to the third interval F on the second surface when viewed through in plan view from the first surface side.

2. The solar cell element according to claim 1, wherein
the first electrodes further comprise a plurality of conduction parts derived from the first surface to the second surface to electrically connect the plurality of main electrode parts and the first output taking parts to each other and located along the alignment direction of the first output taking parts.

3. The solar cell element according to claim 2, wherein
when planarly viewed from the second surface, a distance G between the connection part and the conduction part adjacent to the connection part is larger than a distance H between the connection part and the plurality of main electrode part adjacent to the connection part.

4. The solar cell element according to claim 1, wherein
the plurality of main electrode parts further comprise a third electrode group located outside the first and second electrode groups, and
the plurality of main electrode parts in the third electrode group are located at fourth intervals not less than the third intervals F in a direction orthogonal to the longitudinal direction of plurality of the main electrode parts.

5. The solar cell element according to claim 2, wherein
the number of conduction parts in an alignment direction of the first output taking parts is equal to the number of main electrode parts.

6. The solar cell element according to claim 2, further comprising:
a semiconductor layer of the one conductivity type formed on the second surface, which contains a dopant at a concentration higher than that of the semiconductor substrate, and exhibits the one conductivity type,
wherein the first output taking part comprises a conductor area connected to the conduction part to cover some of the plurality of conduction parts and a taking area located arranged between the conductor area and the collection part and connected to the conductor area,
the collection part is formed on at least a part on the semiconductor layer,
the length of the taking area is shorter than the length of the conductor area in the alignment direction of the first output taking part, and
the semiconductor layer comprises an extending part located between the adjacent taking areas in the alignment direction of the first output taking parts.

7. The solar cell element according to claim 6, wherein
the collection part is located on the extending part.

8. The solar cell element according to claim 6, wherein
the plurality of conduction parts are located in n (n is an integer that is 2 or more) columns, and the columns of the plurality of conduction parts are located on odd-number-th division lines of (2n-1) division lines that equally divide one side of the semiconductor substrate orthogonal to the alignment direction of the first output taking parts by 2n.

9. A solar cell module comprising:
a plurality of solar cell elements according to claim 1 located to be adjacent to each other; and
a wiring material that electrically connects the adjacent solar cell elements to each other,
wherein the plurality of solar cell elements further comprise second output taking parts located on the second surface to be separated from the first output taking parts, and
the wiring material electrically connects the first output taking part of one solar cell element of the adjacent solar cell elements to the second output taking part of the other solar cell element.

10. The solar cell module according to claim 14,
wherein the first output taking part comprises a first area located on the conduction part and a second area located on the second surface except for on the plurality of conduction part, and
the wiring material is separated from the first area of the first output taking part and bonded to the second area of the first output taking part.

11. The solar cell module according to claim 10, further comprising:
a protective layer located between the first area of the first output taking part and the wiring material.

12. The solar cell module according to claim 11, wherein
the protective layer has insulativity.

13. The solar cell module according to claim 10, wherein
the wiring material comprises an upward-convex bent portion located immediately above the first area of the first output taking part and a flat portion in contact with the second region of the first output taking part.

14. A solar cell module comprising:
a plurality of solar cell elements according to claim 2 located to be adjacent to each other; and
a wiring material that electrically connects the adjacent solar cell elements to each other,
wherein the plurality of solar cell elements further comprise second output taking parts located on the second surface to be separated from the first output taking parts, and
the wiring material electrically connects the first output taking part of one solar cell element of adjacent solar cell elements to the second output taking part of the other solar cell element.
